(19) United States
(12) Patent Application Publication
(10) Pub. No.: US 2025/0194322 A1
(43) Pub. Date: Jun. 12, 2025

(54) Full-Color LED Display Using Ultra-Thin LED and Method for Manufacturing Thereof

(71) Applicant: Kookmin University Industry Academy Cooperation Foundation, Seoul (KR)

(72) Inventor: Young Rag DO, Seoul (KR)

(21) Appl. No.: 18/977,388

(22) Filed: Dec. 11, 2024

(30) Foreign Application Priority Data
Dec. 11, 2023 (KR) 10-2023-0178753

(51) Int. Cl. H10H 29/03; H10H 29/14

(52) U.S. Cl. CPC H10H 29/03; H10H 29/142

(57) ABSTRACT

The present invention relates to a full-color LED display and a method for manufacturing thereof. According to this, LED elements with small aspect ratios that are difficult to receive positive dielectrophoretic force can be easily magnetically aligned on the desired electrode, and LED elements can be magnetically aligned on the electrode regardless of the distance between the two electrodes forming the electric field and the size of the LED element.

### CROSS-REFERENCE TO RELATED APPLICATION

This application claims priority to and the benefit of Korean Patent Application No. 10-2023-0178753, filed on Dec. 11, 2023, the disclosure of which is incorporated herein by reference in its entirety.

### BACKGROUND OF THE INVENTION

### (a) Field of the Invention

The present invention relates to a full-color LED display, and more particularly, to a full-color LED display using an ultra-thin LED element and a method for manufacturing thereof.

### (b) Description of the Related Art

Micro LEDs and nano LEDs can implement excellent colors and high efficiency and are eco-friendly materials, so they are used as core materials for various light sources and displays. In line with this market situation, research has recently been conducted to develop a nanocable LED coated with a shell by a new nanorod LED structure or a new manufacturing process. In addition, research and development on a protective film material to achieve high efficiency and high stability of the protective film covering the outer surface of the nanorod and a ligand material that is advantageous for subsequent processes are also underway.

In line with this research in the field of materials, display TVs using red, green, and blue micro-LEDs have recently been commercialized. Micro-LED displays and various light sources have very long and high performance characteristics, theoretical lifespan, and efficiency, but since micro-LEDs must be placed individually on a small electrode in a limited area, it is difficult to manufacture a display that is implemented by placing micro-LEDs on electrodes using pick-place technology as a truly high-resolution commercial display from smartphones to TVs or a light source with various sizes, shapes, and brightness, due to the limitations of process technology, considering high unit prices, high process defect rates, and low productivity. In addition, it is more difficult to arrange nano-LEDs implemented smaller than micro-LEDs individually on electrodes with the same pick and place technology used for micro-LEDs.

To overcome this difficulty, Korean Patent Registration No. 10-2414266 by the inventor of this invention discloses a display manufactured through a method of forming subpixels by magnetically aligning LED elements on two adjacent electrodes using dielectrophoretic force by dropping a solution mixed with LED elements in the subpixel region and forming an electric field between the two alignment electrodes.

However, the magnetic alignment of the LED element using dielectrophoretic force can be mounted to contact the two electrodes only when the LED element receives a positive dielectrophoretic force that moves between the two electrodes that have formed an electric field due to the device movement and alignment mechanism, and if the length of the LED element is less than the spacing between the two electrodes, it may be aligned so as to contact only one of the two electrodes. Therefore, in any case, the LED element cannot be aligned to be in electrical contact with two adjacent electrodes with positive dielectrophoretic force. In addition, positive dielectrophoretic force, which is a major force for magnetically aligning LED elements, is advantageous for rod types with large aspect ratios in the shape of LED elements, and there are limitations to controlling the shape of LED elements, the length of LED elements, and the spacing between the two electrodes to enable magnetic alignment, such as having to implement the spacing between the two electrodes less than or equal to the length of LED elements.

Accordingly, it is urgent to develop a display that can ease the conventional limitations required for magnetic alignment based on LED materials that have a large light-emitting area and minimize or prevent efficiency degradation due to surface defects while more easily implementing electrode placement for addresses when manufacturing subpixels.

### SUMMARY OF THE INVENTION

### Technical Problem

The present invention has been devised to solve the above-mentioned problems, and is directed to providing a full-color LED display and a method for manufacturing thereof in which by overcoming the limitations of magnetic alignment by positive dielectrophoretic force, LED elements with small aspect ratios that are difficult to receive positive dielectrophoretic force can be magnetically aligned, and LED elements can be magnetically aligned on the electrode regardless of the distance between the two electrodes forming the electric field and the size of the LED element.

In addition, the present invention is also directed to providing a full-color LED display and a method for manufacturing thereof in which high luminance can be achieved by increasing the proportion of ultra-thin LED elements that are mounted to be driven by AC power among ultra-thin LED elements that are magnetically aligned on the electrode and by mounting the light emitting surface of the driven LED element to be the front facing the user or the target while minimizing side surface contact that may cause electrical short.

### Technical Solution

In order to solve the above-mentioned problems, the first embodiment of the present invention provides a method for manufacturing a full-color LED display, the method for manufacturing comprising: injecting a solution containing ultra-thin LED elements into multiple subpixel regions in each of which a first electrode line comprising at least two first electrodes spaced apart from each other so that side surfaces of the first electrodes face each other are arranged; forming an electric field by applying power having a frequency of 500 Hz or less to the first electrode line; moving the ultra-thin LED elements located in the electric field into an upper surface of the first electrode; and forming a second electrode on the ultra-thin LED element disposed within the upper surface of the first electrode.

In addition, the second embodiment of the present invention provides a method for manufacturing a full-color LED display, the method comprising: injecting a solution containing ultra-thin LED elements with a light color designated for each subpixel region so that multiple subpixel regions including blue, green, and red subpixel regions are formed in each of which a first electrode line comprising at least two first electrodes spaced apart from each other so that each side surface faces each other is disposed; forming an electric field by applying power having a frequency of 500 Hz or less to the first electrode line; moving the ultra-thin LED elements located in the electric field into an upper surface of the first electrode; and forming a second electrode on the ultra-thin LED element disposed within the upper surface of the first electrode.

According to the first embodiment or second embodiment of the present invention, the power may have a frequency of 1 to 500 Hz and a voltage of 5 to 100 Vpp.

In addition, the viscosity of the solvent may be 50 cP or less.

In addition, the dielectric constant (8) of the solvent may be 5 to 50.

In addition, the ultra-thin LED element is made by stacking layers including a first conductive semiconductor layer, a photoactive layer, and a second conductive semiconductor layer, and a rotation induction film may be further provided for surrounding a side surface of the ultra-thin LED element to generate a rotation torque based on an axial direction perpendicular to a direction in which the layers are stacked.

In addition, the dielectric constant (8) of the rotation induction film may be 3 to 26.

In addition, the ultra-thin LED element may have a ratio (b/a) of a thickness (b), which is a length in a stacking direction of layers, to a long axis length (a) in the cross-section perpendicular to the stacking direction, greater than 0 and less than or equal to 2.0.

In addition, the ratio (b/a) of the ultra-thin LED element may be greater than 0 and less than or equal to 1.8.

In addition, in the first embodiment, the method may further comprise, after forming the second electrode, patterning a color conversion layer on the second electrode corresponding to each subpixel region so that the multiple subpixel regions are independently blue, green, or red subpixel regions.

In addition, the first embodiment of the present invention provides a full-color LED display, comprising multiple subpixel regions, wherein each subpixel region comprises a first electrode line comprising at least two first electrodes whose side surfaces are spaced apart from each other; multiple ultra-thin LED elements each comprising a first ultra-thin LED element disposed in an upper surface of the first electrode; and a second electrode disposed on the first ultra-thin LED element, and wherein the settling ratio in the upper surface of the first electrode calculated according to Mathematical Equation 1 below satisfies 40% or more:

$$First electrode upper surface settling ratio ( \% ) = \frac{\begin{matrix}Number of first ultra - \\ thin LED elements\end{matrix}}{\begin{matrix}Total number of ultra - \\ thin LED elements\end{matrix}} \times 100 \qquad [ Mathematical Equation 1 ]$$

Where, the total number of ultra-thin LED elements refers to the total number of ultra-thin LED elements placed in one subpixel region, and the number of first ultra-thin LED elements refers to the total number of ultra-thin LED elements settled on the upper surface of each of the first electrodes.

In addition, the second embodiment of the present invention provides a full-color LED display, comprising multiple subpixel regions comprising blue, green and red subpixel regions, wherein each subpixel region comprises a first electrode line comprising at least two first electrodes whose side surfaces are spaced apart from each other; multiple ultra-thin LED elements each comprising a first ultra-thin LED element disposed in an upper surface of the first electrode and having a designated light color; and a second electrode disposed on the first ultra-thin LED element, and wherein the settling ratio in the upper surface of the first electrode calculated according to Mathematical Equation 1 below satisfies 40% or more:

$$First electrode upper surface settling ratio ( \% ) = \frac{\begin{matrix}Number of first ultra - \\ thin LED elements\end{matrix}}{\begin{matrix}Total number of ultra - \\ thin LED elements\end{matrix}} \times 100 \qquad [ Mathematical Equation 1 ]$$

Where, the total number of ultra-thin LED elements refers to the total number of ultra-thin LED elements placed in one subpixel region, and the number of first ultra-thin LED elements refers to the total number of ultra-thin LED elements settled on the upper surface of each of the first electrodes.

According to the first embodiment and the second embodiment of the present invention, the ultra-thin LED element is made by stacking layers comprising a first conductive semiconductor layer, a photoactive layer, and a second conductive semiconductor layer, and may include a first surface and a second surface facing each other in the thickness direction, and among the number of first ultra-thin LED elements in one subpixel region, a drivable mounting ratio, which is a ratio of the total sum of the number of third ultra-thin LED elements mounted so that the first surface is in contact with the upper surface of the first electrode and the second surface is in contact with a second electrode line and the number of fourth ultra-thin LED elements mounted so that the second surface is in contact with the upper surface of the first electrode and the first surface is in contact with the second electrode line, may be 40% or more.

In addition, the spacing between the adjacent first electrodes may be 2 to 10 μm.

In addition, the ultra-thin LED element may have a thickness of 0.5 to 1.5 μm, which is the length in a direction in which the layers are stacked, and a long axis length in the cross-section perpendicular to the stacking direction of the layers of 0.5 to 3.0 μm.

In addition, the settling ratio in the upper surface of the first electrode calculated according to Mathematical Equation 1 may be 80% or more, and the drivable mounting ratio may be 50% or more.

In addition, in the first embodiment, the full-color LED display may further comprise, for each subpixel region, a color conversion layer patterned on the second electrode corresponding to the subpixel region so that each subpixel region become a subpixel region expressing any one of blue, green, and red colors.

In addition, the light color of the ultra-thin LED element may be blue, white, or UV.

Hereinafter, terms used in the present invention will be defined.

In the description of the embodiment according to the present invention, when a component is described as being formed “on”, “on top of”, “under”, and “on bottom of” each layer, region, pattern, or substrate, “on”, “on top of”, “under”, and “on bottom of” include both the meanings of “directly” and “indirectly.”

In addition, as a term used in the present invention, the “drivable mounting ratio” refers to the ratio of the number of LED elements mounted in a drivable form among all LED elements mounted in the upper surface of the first electrode. In this case, an LED element mounted in a drivable form refers to an LED element mounted so that, among a first surface and a second surface facing in the thickness direction, which is a direction in which multiple layers of LED elements are stacked, the first surface is in contact with the upper surface of the first electrode, and an LED element mounted so that the second surface of the LED element is in contact with the upper surface of the first electrode. In the end, the drivable mounting ratio is a ratio of the total sum of the number (M) of the ultra-thin LED elements mounted so that the first surface is in contact with the upper surface of the first electrode and the number (N) of the ultra-thin LED elements mounted so that the second surface is in contact with the upper surface of the first electrode among the first ultra-thin LED elements, compared to the total number (L) of the first ultra-thin LED elements placed in the upper surface of the first electrode placed in one subpixel region, and is calculated by the calculation formula [(M+N)/L]×100.

Meanwhile, it is noted that the present invention was invented with the support of the following national research and development task.

[National Research and Development Project 1 that supported this invention]

[Assignment Unique Number] 1711130702 [Assignment Number] 2021R1A2C2009521

[Name of the Ministry] Korea Ministry of Science and ICT [Assignment management (professional) organization name] National Research Foundation of Korea

[Research Project Name] Mid-sized Research Support Project

[Research Assignment Name] Development of Dot-LED Materials and Display Source/Application Technology

[Contribution rate] 50/100 [Name of Project Carrying Out Organization] Kookmin University Industry Academic Cooperation Foundation

[Research Period] 2021.03.01-2026.02.28 [National Research and Development Project 2 that supported this invention]

[Assignment Unique Number] 1711199993 [Assignment Number] 00281346 (RS-2023-00281346)

[Name of the Ministry] Korea Ministry of Science and ICT [Assignment management (professional) organization name] National Research Foundation of Korea

[Research Project Name] Nano and Material Technology Development Project (strategic type)

[Research Assignment Name] Development of 300 ppi class high resolution inorganic light emitting display materials and process technology that can be stretched more than 30% inherently [Contribution rate] 50/100

[Name of Project Carrying Out Organization] Hongik University Industry Academic Cooperation Foundation [Research Period] 2023.08.01-2027.12.31

### Advantageous Effect

The method for manufacturing a full-color LED display according to the present invention can settle LED elements in a high proportion within one electrode surface regardless of the distance between two electrodes forming an electric field or the size of the LED element, even when using LED elements that have a small aspect ratio that is difficult to receive positive dielectrophoretic force or do not have a separate layer such as a magnetic layer to attract an electrode. In addition, by increasing the proportion of ultra-thin LED elements mounted drivable by AC power among ultra-thin LED elements settled within the electrode surface, side surface contact that may cause electrical short can be minimized, thereby implementing a display with high luminance. In addition, the limitation of electrode arrangement design implementing subpixels is reduced, so it can be widely applied to various displays.

### BRIEF DESCRIPTION OF THE DRAWINGS

FIGS. 1 to 3 are views of a full-color LED display according to a first embodiment of the present invention, where FIG. 1 is a schematic plan view of a display part in which a plurality of subpixel regions are arranged, FIG. 2 is a partial enlarged view of FIG. 1, and FIG. 3 is a cross-sectional schematic view taken along X-X′ boundary line of FIG. 2.

FIG. 4 is a cross-sectional view of an ultra-thin LED element included in an exemplary embodiment of the present invention.

FIG. 5 is a schematic diagram for describing the magnetic alignment of ultra-thin LED elements by dielectrophoretic force, where (a) is a diagram in which a solution containing ultra-thin LED elements is treated on first electrodes spaced apart from each other, (b) is a diagram showing a magnetically aligned aspect of ultra-thin LED elements according to negative dielectrophoretic force by the electric power applied to the first electrodes, and (c) is a diagram showing a magnetically aligned aspect of ultra-thin LED elements according to a positive dielectrophoretic force by the electric power applied to the first electrodes.

FIGS. 6 to 8 are graphs simulating a distance moved by a cylindrical ultra-thin LED element under different conditions in a state in which a solution containing the cylindrical ultra-thin LED element with a thickness, which is a length in the stacking direction, of 1.05 μm, a surface diameter perpendicular to the stacking direction is 750 nm, and an n-type conductive semiconductor layer, a photoactive layer, and a p-type conductive semiconductor layer is treated on first electrodes with a width of 10 μm spaced apart from each other at spacings of 2 μm, where FIG. 6 is a graph simulating a distance moved by the ultra-thin LED element by the action of four forces when the frequency is changed while the voltage of power applied to the first electrodes is fixed at 10 Vpp, FIG. 7 is a graph simulating a distance moved by the ultra-thin LED element by changing a type of solvent, and FIG. 8 is a graph simulating a distance moved by the ultra-thin LED element by changing a voltage of an applied power.

FIG. 9 is a cross-sectional view of an ultra-thin LED element according to an exemplary embodiment of the present invention.

FIG. 10 is a mimetic diagram showing that, above the first electrodes where an electric field is formed in step 3 according to an exemplary embodiment of the present invention, an ultra-thin LED element placed in a solvent moves into an upper surface of the first electrodes by electroosmotic pressure and then is magnetically aligned, where (a) is a diagram that mimics rotation torque generated in the device based on the x-axis perpendicular to the thickness direction (d) of the ultra-thin LED element, and (b) is a diagram that mimics that one end surface of the ultra-thin LED element in the thickness direction is mounted to contact the upper surface of the first electrodes by rotation torque.

FIG. 11 is a cross-sectional view of an ultra-thin LED element according to an exemplary embodiment of the present invention.

FIGS. 12 and 13 are views of a full-color LED display according to a second embodiment of the present invention, where FIG. 12 is a schematic plan view of a display part on which multiple subpixel regions are arranged, and FIG. 13 is a cross-sectional schematic view taken along Y-Y′ boundary line of FIG. 12.

FIGS. 14 to 18 are SEM photographs taken after step 3 in a process of manufacturing a full-color LED display according to various embodiments of the present invention.

FIG. 19 is a photograph obtained by applying driving power, which is a direct current of 5V, to one subpixel of a full-color LED display according to Example 1 and then emitting light.

### DETAILED DESCRIPTION OF THE EMBODIMENTS

Hereinafter, exemplary embodiments of the present invention will be described in detail so that those of ordinary skill in the art can readily implement the present invention with reference to the accompanying drawings. The present invention may be embodied in many different forms and is not limited to the embodiments set forth herein.

First, a full-color LED display according to the first embodiment of the present invention and a method for manufacturing thereof will be described.

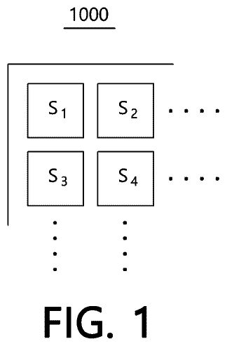

Referring to FIGS. 1 to 3, the full-color LED display 1000 according to the first embodiment of the present invention includes multiple subpixel regions S₁,S₂, S₃, S₄, wherein each of the subpixel regions S₁,S₂,S₃, S₄ includes a first electrode line 210 including at least two first electrodes 211 and 212 spaced apart from each other in their side surfaces, multiple ultra-thin LED elements 100 including first ultra-thin LED elements 100A, 100B, and 100C disposed on the upper surfaces of the first electrodes 211 and 212, and a second electrode line 220 including second electrodes 221 and 222 disposed on the first ultra-thin LED elements 100A, 100B, and 100C.

Specifically, the full-color LED display 1000 has a display panel that includes a display part in which multiple subpixel regions S₁, S₂, S₃, S₄ are arranged on the x-y plane based on mutually perpendicular x, y, and z axes.

In addition, the display panel may further include a non-display part located on the outer side of the display part. In addition, the full-color LED display 1000 may further include known components constituting a display, such as a gate driving circuit for driving the display panel, a data driving circuit, and a controller, and all or some of these known components may be placed in the non-display part, for example. Meanwhile, known components constituting a display, such as a controller or various driving circuits, may have known structures and functions in the display field, so the detailed description thereof is omitted in the present invention.

In addition, a gate driving circuit and a data driving circuit are connected to the controller, and a number of gate lines and a number of data lines connected to the gate driving circuit and the data driving circuit, respectively, may be arranged on the x-y plane in the above display part.

In addition, the subpixel regions S₁, S₂, S₃, S₄ may be located within an area where the gate lines and the data lines intersect, for example. In addition, ultra-thin LED elements 100 are provided in each of the subpixel regions S₁, S₂, S₃, S₄, and each of the subpixel regions S₁, S₂, S₃, S₄ may represent the light color emitted by the ultra-thin LED element 100, and the light color above may be substantially the same.

Specifically, the subpixel regions S₁, S₂, S₃, S₄ may include the same ultra-thin LED element 100 that emits a certain color, and a patterned color conversion layer 700 may be implemented on the second electrodes 221 and 222 corresponding to each of the subpixel regions S₁, S₂, S₃, S₄ so that the subpixel regions S₁, S₂, S₃, S₄ emit light colors corresponding to R, G, and B. In this case, the subpixel regions S₁, S₂, S₃, S₄ are not configured to emit only light colors corresponding to R, G, and B, and a part of R, G, and B may be substituted, or a sub-pixel region emitting yellow or white light may be included together therewith.

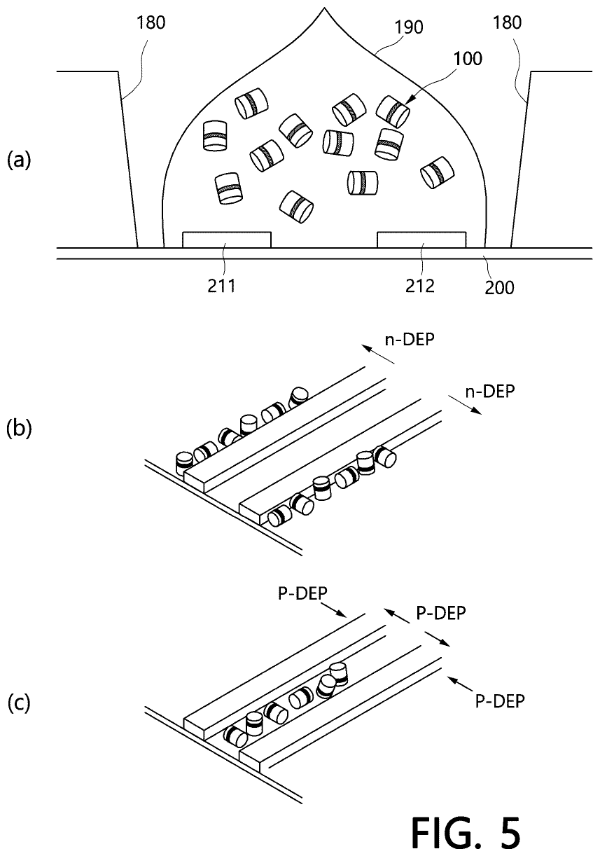

In addition, the sizes of each of the subpixel regions S₁, S₂, S₃, S₄ may all be the same or may be configured to be different according to a specified light color. In addition, FIG. 1 illustrates that subpixel regions S₁, S₂, S₃, S₄ are arranged continuously in a row by forming rows and columns, but it is not limited to this, and it is noted that they can be arranged in various arrangements rather than in a row or in non-continuous arrangements by forming rows and columns. In addition, the spacing between subpixel regions S₁, S₂, S₃, S₄ may be implemented on the x-y plane of the display part at equal spacings in the x-axis direction and y-axis direction, but is not limited to this. In addition, for example, each of the subpixel regions S₁, S₂, S₃, S₄ may be divided by a partition wall (180 in FIG. 5) surrounding the ultra-thin LED elements 100.

In addition, in the subpixel regions S₁, S₂, S₃, S₄, at least two subpixel regions may constitute one pixel, and the configuration of the pixel may employ known technology in the display field, so the present invention is not particularly limited thereto.

In addition, each of the subpixel regions S₁, S₂, S₃, S₄ may be driven independently. In addition, the subpixel regions S₁, S₂, S₃, S₄ may have an area of 100 cm² or less, as an example, 100 mm² or less, as another example, 1 μm² to 100 mm², yet another example, 10 μm² to 10 mm², still yet another example, but are not limited thereto.

In addition, the display part in the display panel may be divided into a first layer region where the ultra-thin LED elements 100 provided in each of the multiple subpixel regions S₁, S₂, S₃, S₄ are located in the z-axis direction, and a second layer region where circuit devices such as various thin film transistors and electrode patterns are placed to independently emit light of the ultra-thin LED elements 100 in each of the subpixel regions S₁, S₂, S₃, S₄. In this case, the second layer region may be located under the base substrate 300 in the first layer region.

The full-color display 1000 according to an embodiment of the present invention implementing the first layer region of each of the plurality of subpixel regions S₁, S₂, S₃, S₄ may be implemented by including a step of injecting a solution containing ultra-thin LED elements 100 into a plurality of subpixel regions S₁, S₂, S₃, S₄ in each of which a first electrode line 210 including at least two first electrodes 211 and 212 spaced apart from each other so that side surfaces thereof face each other are arranged (step 1), a step of forming an electric field by applying power having a frequency of 500 Hz or less to the first electrodes 211 and 212 (step 2), a step of moving the ultra-thin LED elements 100 located in the electric field into the upper surfaces of the first electrodes 211 and 212 (step 3), and a step of forming second electrodes 221 and 222 on the first ultra-thin LED elements 100A, 100B, and 100C arranged in the upper surfaces of the first electrodes 211 and 212 (step 4).

First, as step 1, a step of injecting a solution containing ultra-thin LED elements 100 into multiple subpixel regions S₁, S₂, S₃, S₄ in each of which a first electrode line 210 is arranged is performed.

The first electrode line 210 includes at least two first electrodes 211 and 212 spaced apart from each other so that side surfaces thereof face each other.

The first electrodes 211 and 212 provide an upper surface that becomes a mounting surface on which an ultra-thin LED element 100 injected on the first electrode line 210 is mounted. The upper surface may be one exposed surface of the first electrodes 211 and 212 substantially parallel to the surface of a base substrate 300 on which the first electrodes 211 and 212 are formed.

In addition, the first electrodes 211 and 212 perform a function of forming an electric field capable of moving and aligning the injected ultra-thin LED elements 100 into the upper surfaces of the first electrodes 211 and 212. Accordingly, at least two first electrodes 211 and 212 are provided in each of the subpixel regions S₁, S₂, S₃, S₄ to form an electric field by power applied thereto. In addition, the first electrodes 211 and 212 may function as driving electrodes for emitting ultra-thin LED elements 100 along with the second electrodes 221 and 222. In other words, the same type of power is applied to the first electrodes 211 and 212 when the full-color LED display 1000 is driven, and even if the spacing between the first electrodes 211 and 212 is designed to be narrow, there is little risk of an electric short when the full-color LED display 1000 is driven, and when the full-color LED display 1000 is manufactured, an electric field of a large intensity may be formed, which is advantageous for the movement and alignment of the injected ultra-thin LED elements 100. In addition, there is an advantage in that it is easy to design the first electrode line 210 by reducing the limitation of the design of the spacing between the first electrodes.

Meanwhile, the specific circuit design of the first electrode line 210, in which the first electrodes 211 and 212 are designed to perform the above functions, may be achieved by appropriately employing and changing the technology for known circuit design employed in the display, so the present invention is not particularly limited in this regard. In addition, the number, thickness, width, shape, and arrangement of the first electrodes 211 and 212 may employ a known display electrode line or appropriately change it according to the purpose, so the present invention is not particularly limited thereto. For example, the first electrodes 211 and 212 may be aluminum, chromium, gold, silver, copper, graphene, ITO, or an alloy thereof, and may have a width of 2 to 50 μm and a thickness of 0.1 to 100 μm.

In addition, the first electrodes 211 and 212 may be formed on a base substrate 300, for example. The base substrate 300 may function as a support body for supporting a display part. The base substrate 300 may be a known substrate used in a light source such as a display, and the present invention is not particularly limited to the material, area, thickness, and the like of the base substrate 300. For example, the base substrate 300 may be transparent in consideration of light transmittance, and specifically, glass or plastic may be selected, but is not limited thereto. In addition, the base substrate 300 may be a bendable material, for example. In addition, the size and thickness of the base substrate 300 may be appropriately changed in consideration of the size and number of ultra-thin LED elements provided, and the specific design of the first electrode line 210, so the present invention is not particularly limited in this regard.

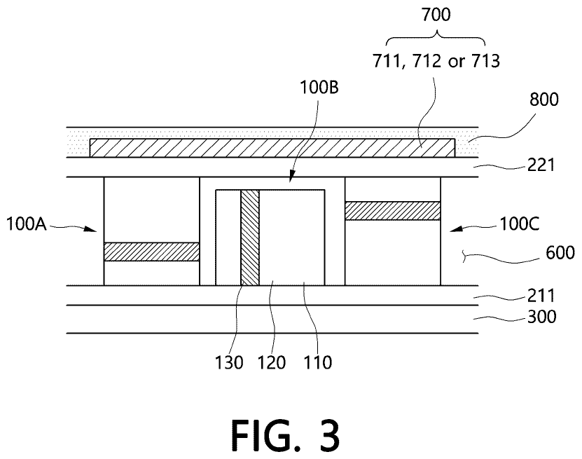

Meanwhile, it should be noted that unlike the one shown in FIG. 3, the first electrode line 210 may be formed on a passivation layer having a flat surface rather than on the base substrate 300, and known circuit components used for displays such as thin film transistors may be placed in the lower part of the passivation layer.

In addition, a solution containing multiple ultra-thin LED elements 100 injected on the first electrode line 210 described above includes an ultra-thin LED element 100 and a solvent.

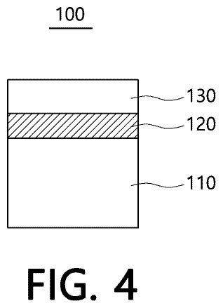

The ultra-thin LED element 100 may be a known LED element used for a light source. Referring to FIG. 4, the ultra-thin LED element 100 may include a first conductive semiconductor layer 110, a second conductive semiconductor layer 130, and a photoactive layer 120 disposed between the first conductive semiconductor layer 110 and the second conductive semiconductor layer 130 in a direction in which layers are stacked.

In addition, one of the first conductive semiconductor layer 110 and the second conductive semiconductor layer 130 may include at least one n-type semiconductor layer, and the other conductive semiconductor layer may include at least one p-type semiconductor layer. In addition, the direction in which these multiple layers are stacked is defined as the thickness direction of the ultra-thin LED element 100, and the surfaces of the ultra-thin LED element 100 facing in the thickness direction are referred to as the first surface and the second surface, respectively, and will be described below based on this. For example, in the case of an ultra-thin LED element having the first conductive semiconductor layer 110, the photoactive layer 120, and the second conductive semiconductor layer 130, the first surface is one surface of the first conductive semiconductor layer 110 or the second conductive semiconductor layer 130, and the second surface is one surface of the second conductive semiconductor layer 130 or the first conductive semiconductor layer 110.

When the first conductive semiconductor layer 110 includes an n-type semiconductor layer, the n-type semiconductor layer may be at least one selected from semiconductor materials having a composition formula of InₓAl_{y}Ga_{1-x-y}N (0≤x≤1, 0≤y≤1, 0≤x+y≤1), for example, InAlGaN, GaN, AlGaN, InGaN, AlN, InN, and the like, and may be doped with a first conductive dopant (e.g., Si, Ge, Sn, etc.). According to a preferred embodiment of the present invention, the thickness of the first conductive semiconductor layer 110 including the n-type semiconductor layer may be 0.2 to 3 μm, but is not limited thereto.

When the second conductive semiconductor layer 130 includes a p-type semiconductor layer, the p-type semiconductor layer may be at least one selected from semiconductor materials having a composition formula of InₓAl_{y}Ga_{1-x-y}N (0≤x≤1, 0≤y≤1, 0≤x+y≤1), for example, InAlGaN, GaN, AlGaN, InGaN, AlN, InN, and the like, and may be doped with a second conductive dopant (e.g., Mg). According to a preferred embodiment of the present invention, the thickness of the second conductive semiconductor layer 130 including the p-type semiconductor layer may be 0.01 to 0.35 μm, but is not limited thereto.

Next, the photoactive layer 120 is formed between the first conductive semiconductor layer 110 and the second conductive semiconductor layer 130, and may be formed in a single or multiple quantum well structure. The photoactive layer 120 may be used without limitation in the case of a photoactive layer included in a conventional LED element used for lighting, display, and the like. A clad layer (not shown) doped with a conductive dopant may be formed above and/or below the photoactive layer 120, and the clad layer doped with a conductive dopant may be implemented as an AlGaN layer or an InAlGaN layer. In addition, materials such as AlGaN and AlInGaN may also be used as the photoactive layer 120. In the photoactive layer (120), when an electric field is applied to the device, electrons and holes moving from the conductive semiconductor layers located respectively above and below the photoactive layer to the photoactive layer generate a bond of electron-hole pairs in the photoactive layer, thereby emitting light. According to a preferred embodiment of the present invention, the thickness of the photoactive layer 120 may be 30 to 300 nm, but is not limited thereto.

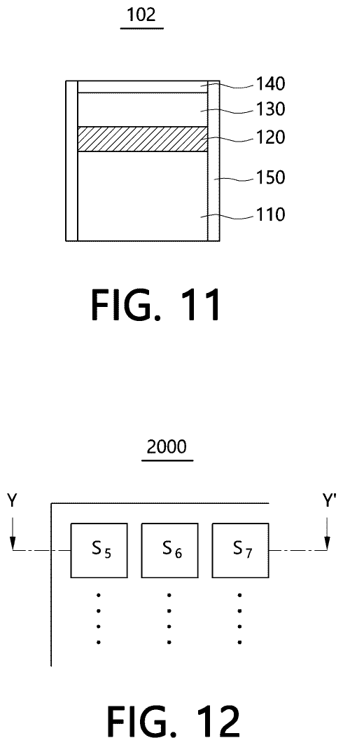

In addition, the ultra-thin LED element 100 is shown to include the first conductive semiconductor layer 110, the photoactive layer 120, and the second conductive semiconductor layer 130 as the minimum components, but it should be noted that other active layers, conductive semiconductor layers, phosphor layers, hole block layers, and/or electrode layers may be included above and below each layer. For example, an electrode layer 140 may be further included as shown in FIG. 11. The electrode layer 140 may be used without limitation in the case of a conventional electrode layer provided in an LED element, and as a non-limiting example thereof, Cr, Ti, Al, Au, Ni, ZnO, AZO, ITO, and an oxide or alloy thereof may be used alone or in combination, but is not limited thereto. In addition, the thickness of the electrode layer 140 may be 10 to 500 nm, but is not limited thereto.

In addition, the shape of the cross-section perpendicular to the direction in which the layers of the ultra-thin LED element 100 are stacked is shown as a circular shape, but it is not limited thereto, and it should be noted that the cross-sectional shape of the ultra-thin LED element may be employed without limitation from general polygonal shapes such as square, rectangle, rhombus, parallelogram, trapezoid, etc. to ellipse, etc.

In addition, the size of the ultra-thin LED element 100 may have a nano- or micro-scale size that makes it difficult to mount the LED element with pick-and-place technology. For example, the thickness, which is the length in a direction in which the layers of the ultra-thin LED element are stacked, may be 0.5 μm to 1.5 μm. In addition, the size of the cross-section perpendicular to a direction in which the layers are stacked may be defined differently depending on the shape, but for example, if the shape of the cross-section is a non-polygon such as a circle or ellipse, it may be a diameter with the longest length among the line segments crossing the cross-sectional border, and the diameter may be 0.5 to 3.0 μm. In addition, when the cross section is polygonal, the length of one side thereof may be 0.5 to 3.0 μm.

The above-described ultra-thin LED element 100 is injected on the first electrode line 210 in a solution state dispersed in a solvent, and the solvent has a function of a dispersion medium for dispersing the ultra-thin LED element 100. The solvent may be used without limitation as long as it is a solvent that can increase the dispersibility of the ultra-thin LED element 100 without causing physical and chemical damage to the ultra-thin LED element 100. For example, the solvent may be one solvent or a mixture of two or more solvents such as acetone, isopropyl alcohol, ethanol, polyethylene glycol, propylene glycol methyl ether acetate (PGMEA), hexane, dodecane, and the like.

In addition, a solution containing the ultra-thin LED elements 100 may be injected on the first electrode line 210 using a known method. For example, for the solution, a known device for discharging the solution, for example, a printing device such as an inkjet printer, a spraying device, or a discharging device such as a dispenser, may be used. In addition, the solution containing the ultra-thin LED elements 100 may be implemented with ink or paste to suit each discharge device, and the type of solvent may be appropriately selected in consideration of physical properties such as required viscosity. Meanwhile, the injection method for each discharge device may be based on a known method for each discharge device, and the present invention is not particularly limited in this regard. In addition, the solution may further include additives such as a dispersant added to the ink or paste commonly used in the discharge device. In addition, the solution containing the ultra-thin LED elements may contain the ultra-thin LED element in an amount of 0.01 to 99.99% by weight in the solution, and the present invention is not particularly limited in this regard.

Meanwhile, on the first electrode line 210, a partition wall (180 of FIG. 5) made up of a sidewall surrounding a desired region at a certain height may be further included to prevent the injected ultra-thin LED elements 100 from flowing to parts other than the desired region and to concentrate and arrange the ultra-thin LED elements 100 on the desired region, and the solution containing the ultra-thin LED elements 100 may be injected into within the partition wall 180. The partition wall 180 may be formed of an insulating material so as not to affect an electrical effect when the ultra-thin LED elements 100 are driven in the final full-color LED display 1000 in which the ultra-thin LED elements 100 are mounted. Preferably, the insulating material may be any one or more of inorganic insulating materials such as silicon dioxide (SiO₂), silicon nitride (Si₃N₄), aluminum oxide (Al₂O₃), hafnium oxide (HfO₂), yttrium oxide (Y₂O₃), titanium dioxide (TiO₂), and various transparent polymer insulating materials. In addition, the partition wall 180 may be made through patterning and etching processes so that the insulating material is formed on the first electrode line 210 at a certain height and then becomes a sidewall surrounding the desired region.

In this case, if the material is an inorganic insulating material, the partition wall 180 may be formed by any one of chemical vapor deposition, atomic layer deposition, vacuum deposition, e-beam deposition, and spin coating methods. In addition, if the material is a polymer insulating material, it may be formed using coating methods such as spin coating, spray coating, and screen printing. In addition, the patterning above may be formed through photolithography using photosensitive materials or may be performed by known nano-imprinting methods, laser interference lithography, electron beam lithography, etc. At this time, the height of the formed partition wall 180 is more than or equal to ½ of the thickness of the ultra-thin LED element 100, and generally, it may be preferably 0.1 to 100 μm, and more preferably 0.3 to 10 μm as a thickness that may not affect the post-process after magnetic alignment. If the above range is not satisfied, it may affect the post-process. In particular, if the height of the partition wall 180 is excessively lower compared to the thickness of the ultra-thin LED element 100, the solution containing the ultra-thin LED elements 100 may overflow outside the partition wall 180, causing a difference in the number of ultra-thin LED elements placed within the partition wall, resulting in uneven luminance for each subpixel region.

In addition, when manufacturing the partition wall 180, the etching above may adopt an appropriate etching method in consideration of the material of the insulating material, and for example, may be performed through wet etching or dry etching, and may be preferably performed by one or more dry etching methods of plasma etching, sputter etching, reactive ion etching, and reactive ion beam etching.

Meanwhile, the step 1 is explained that the ultra-thin LED elements 100 are injected in a solution mixed with a solvent, but it should be noted that the same case as the solution is injected as a result is also included in step 1 such as a case in which the ultra-thin LED elements 100 are first injected on the first electrode line 210 and then the solvent is injected or a case in which the solvent is injected first and then the ultra-thin LED elements 100 are injected.

Next, as step 2 of the first embodiment, a step of forming an electric field by applying power having a frequency of 500 Hz or less to the first electrode line including an adjacent first electrodes 211 and 212 is performed.

The step 2 may be performed before, simultaneously with, or after the step 1 described above. That is, the power applied to the first electrodes 211 and 212 may be applied before, simultaneously with, or after the solution containing the ultra-thin LED elements 100 are injected on the first electrodes 211 and 212, and the present invention does not particularly limit the timing of applying power applied to the first electrodes 211 and 212.

In addition, the step 2 is a step of applying power having a frequency of 500 Hz or less to the adjacent first electrodes 211 and 212, and the electric field formed by the application of the power exerts a force that moves and aligns the ultra-thin LED elements 100 on the upper surfaces of the first electrodes 211 and 212. Hereinafter, the above force will be described first.

The electric field formed by the power having a frequency of 500 Hz or less applied to the first electrodes 211 and 212 may independently move and align the ultra-thin LED elements 100 to be located in the upper surface of any one of the first electrodes 211 and 212. This movement and alignment pattern is a result of the dominance of electroosmotic pressure among the various forces applied to the ultra-thin LED elements 100, which is a pattern different from the magnetic alignment of LED elements when dielectrophoretic force, which is another force competing with electroosmotic pressure, becomes dominant.

Specifically, to explain the mechanism of dielectrophoresis first, dielectrophoresis refers to a phenomenon in which a directional force is applied to a particle by a dipole induced by the particle when the particle is placed in a non-uniform electric field. In this case, the intensity of the force may vary depending on the electrical characteristics of the particle and the medium, the dielectric characteristics, the frequency of the AC electric field, and the like and the average force (F_{DEP}) received by the particle during dielectrophoresis is shown in Mathematical Equation 1 below.

$${F}_{DEP} = 2 π {r}^{3} {ε}_{m} Re [ K ( ω ) ] ∇ {\vert E \vert}^{2} \qquad [ Mathematical Equation 1 ]$$

In Mathematical Equation 1, r, εₘ, and E represent the radius of the particle, the dielectric constant of the medium, and the root mean square magnitude of the applied AC electric field, respectively. In addition, Re [K(ω)] is a factor that determines the direction in which a particle close to a spherical shape moves, and means the real number part of the value according to Mathematical Equation 2 below.

$$K ( ω ) = \frac{{ε}_{p}^{*} - {ε}_{m}^{*}}{{ε}_{p}^{*} + 2 {ε}_{m}^{*}} \qquad [ Mathematical Equation 2 ]$$

Where, εₚ* and εₘ* are the complex dielectric constant of the particle and the medium, respectively, and ¿* is given according to Mathematical Equation 3 below.

$${ε}^{*} = ε - j \frac{σ}{ω} \qquad [ Mathematical Equation 3 ]$$

Where, σ is the electrical conductivity coefficient, ε is the dielectric constant, ω is the angular frequency (ω)=2πf), and j is the imaginary part (j=\sqrt{−1}) this case, the movement of the particles during dielectrophoresis depends heavily on a change in the factor according to Mathematical Equation 2, and specifically, the movement of the particles located in the electric field may be determined by a change in the sign of Re [K (ω)] according to the frequency of the applied power. For example, if Re [K (ω)] has a positive value, the particles move to the high electric field domain, that is, to the two electrodes that have formed an electric field, which is called positive dielectrophoresis (positive DEP or p-DEP). In addition, if Re [K (ω)] has a negative value, the particles may move away from the high electric field domain, that is, away from the two electrodes that form an electric field, which is called negative dielectrophoresis (negative DEP or n-DEP).

This mechanism of dielectrophoresis applies equally to the ultra-thin LED element 100 located together with a solvent, which is a medium, on the two electrodes that have formed an electric field.

Referring to FIG. 5, negative dielectrophoretic force (n-DEP) or positive dielectrophoretic force (p-DEP) may be applied to ultra-thin LED elements 100 located in a mixed state with a solvent 190 in an electric field formed by applying different power to the first electrodes 211 and 212 spaced apart from each other, depending on the size and frequency of the electric field, the dielectric constant of the solvent 190, the shape of the ultra-thin LED element, and the device material in the state of (a) of FIG. 5, and if negative dielectrophoretic force (n-DEP) is applied to the ultra-thin LED elements 100, the ultra-thin LED elements 100 are moved away from the region where the electric field is formed and are aligned outside the first electrodes 211 and 212 as shown in (b) of FIG. 5. Alternatively, if positive dielectrophoretic force (p-DEP) is applied to the ultra-thin LED elements 100 in the state (a) of FIG. 5, the ultra-thin LED elements 100 are moved and aligned between the two adjacent first electrodes 211 and 212 with the strongest electric field, as shown in (c) of FIG. 5.

In this time, the ultra-thin LED elements 100 moved and aligned as shown in (b) of FIG. 5 are aligned on the side away from the first electrodes 211 and 212, so the ultra-thin LED elements 100 cannot be moved and mounted on the upper surfaces of the first electrodes 211 and 212. In addition, even in the case of ultra-thin LED elements 100 moved and aligned as shown in (c) of FIG. 5, the ultra-thin LED elements cannot be moved and mounted on the upper surfaces of the first electrodes 211 and 212. Furthermore, in either case of (b) of FIG. 5 and (c) of FIG. 5, the ultra-thin LED elements are not operable.

However, as can be seen in (c) of FIG. 5, since when positive dielectrophoretic force is used, the LED elements can be aligned to move between the two adjacent first electrodes 211 and 212 and climb on the upper surfaces of the two adjacent first electrodes 211 and 212 at the same time, there is only room to change the design so that the LED elements are to be operable by aligning them on the two adjacent first electrodes 211 and 212 under limited conditions of lengthening the length of the LED element so that a larger amount of positive dielectrophoretic force is applied and adjusting the spacing between the first electrodes 211 and 212 to be smaller than the length of the LED element.

Therefore, in any case, using positive dielectrophoretic force and negative dielectrophoretic force, LED elements cannot be moved and aligned into the upper surface of either of the two adjacent first electrodes that have formed an electric field, and if the aspect ratio of the shape of the LED element is small, the amount of positive dielectrophoretic force applied to the LED element is also not large, so magnetic alignment may not be smoothly performed even if the size of the LED element and the spacing between the first electrodes are adjusted.

Accordingly, the inventor of the present invention has found that the electroosmotic pressure is a predominant force applied to the ultra-thin LED elements when controlling the magnitude of the frequency of the applied power while continuing to study the movement and magnetic alignment mechanism of the LED elements on the two electrodes having the electric field formed thereon, and thus it is possible to have a different form of magnetic alignment from the previously known magnetic alignment aspects of LED elements by positive dielectrophoretic force in the electric field, i.e. the LED elements can be moved and aligned into the upper surface of one electrode among two adjacent electrodes having the electric field formed thereon, and has come to the present invention.

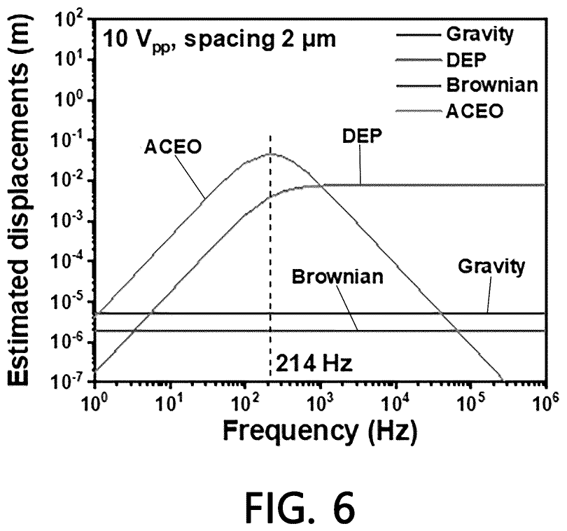

Specifically, when an electric field is applied to an ultra-thin LED element, the forces applied to the ultra-thin LED element are gravity, Brownian kinetic force, dielectrophoretic force, and electroosmotic pressure. Describing this by referring to FIG. 6, when the distance traveled by the ultra-thin LED element by each force applied to the ultra-thin LED element is simulated using the frequency of the electric field as a variable, the distance traveled by the ultra-thin LED element due to gravity and Brownian kinetic force hardly changes depending on the frequency of the electric field. On the other hand, the distance traveled by the ultra-thin LED element varies depending on the frequency of the electric field due to electroosmotic pressure and dielectrophoretic force, and depending on the frequency, the ultra-thin LED element with the dominant electroosmotic pressure is moved on the upper surface of one of the two adjacent first electrodes that have formed an electric field, and the ultra-thin LED element with the dominant dielectrophoretic force is moved between the two adjacent first electrodes, and these two forces may compete.

Specifically, as shown in FIG. 6, in the case of a cylindrical ultra-thin LED element with a thickness, which is the length in a direction in which the layers are stacked, of 1.05 μm, a surface diameter perpendicular to the stacking direction of 750 nm, and an n-type conductive semiconductor layer, photoactive layer, and p-type conductive semiconductor layer; under the conditions that the distance between the adjacent first electrodes is 2 μm, the intensity of the applied power is 10 Vpp, and the solvent is acetone, if the frequency of the power applied to the first electrode is less than or equal to 1 kHz, electroosmotic pressure is the most dominant force applied to the ultra-thin LED element, and if the frequency exceeds 1 kHz, dielectrophoretic force is the most dominant force applied to the ultra-thin LED element, and as a result, when the frequency of the applied power is less than or equal to 1 kHz, it becomes more advantageous to move and align the ultra-thin LED element on the upper surface of the first electrode.

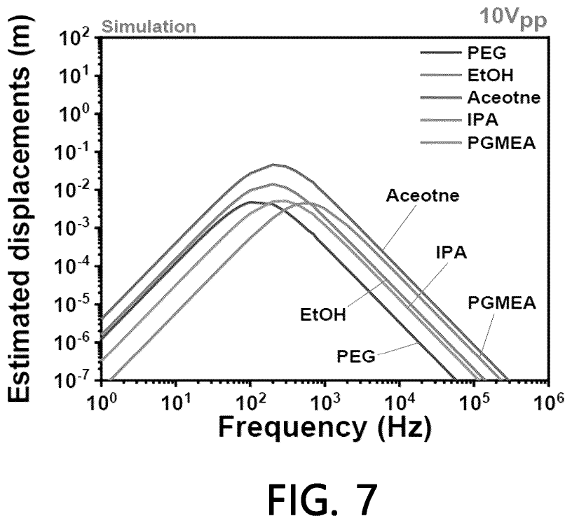

In addition, as shown in FIG. 7, depending on the type of solvent that moves the ultra-thin LED element, the frequency at which the dominant force applied to the ultra-thin LED element becomes electroosmotic pressure may vary. However, even if the frequency at which the electroosmotic pressure is maximized varies depending on the type of solvent, it can be seen that as the electroosmotic pressure reaches its maximum at frequencies less than or equal to 1 kHz, especially less than or equal to 500 Hz, the electroosmotic pressure can still be the dominant force at frequencies less than or equal to 1 kHz, especially less than or equal to 500 Hz.

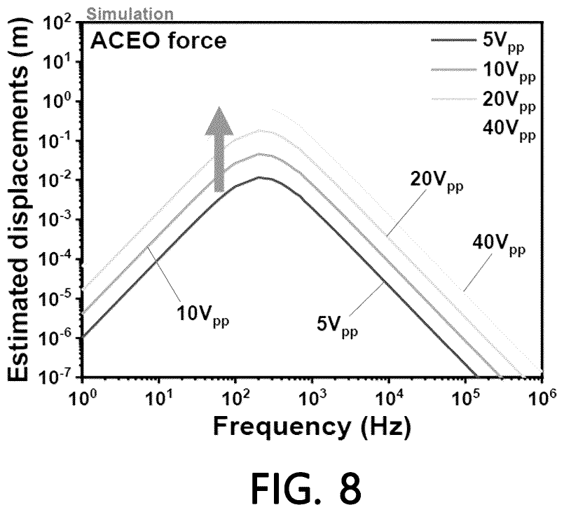

However, as shown in FIG. 8, the distance that the ultra-thin LED element travels due to electroosmotic pressure increases when the voltage of the power source increases, but even if the voltage changes, the frequency at which the electroosmotic pressure is maximized is the same as less than or equal to 1 kHz, especially less than or equal to 500 Hz, and it can be seen that even if the voltage increases, the force applied to the ultra-thin LED element does not transfer from the region dominated by electroosmotic pressure to the region dominated by dielectrophoretic force.

Accordingly, the method for manufacturing a full-color LED display 1000 according to an exemplary embodiment of the present invention performs a step of applying power having a frequency of 500 Hz or less to the first electrodes 211 and 212 so that the dominant force applied to the ultra-thin LED element 100 to be located in the electric field formed by the two adjacent first electrodes 211 and 212 becomes electroosmotic pressure (step 2). If the frequency of the applied power exceeds 500 Hz, the force applied to the ultra-thin LED element 100 competes with the dielectrophoretic force, and if the frequency becomes larger, the proportion of ultra-thin LED elements located on the upper surface of any one first electrode may be significantly reduced compared to the number of injected ultra-thin LED elements. Accordingly, the power applied to the first electrodes 211 and 212 may preferably have a frequency of 1 Hz to 500 Hz and a voltage of 5 to 100 Vpp, more preferably a frequency of 1 to 50 Hz and a voltage of 5 to 80 Vpp, yet more preferably a frequency of 1 to 30 Hz and a voltage of 5 to 50 Vpp, still yet more preferably a frequency of 5 to 20 Hz and a voltage of 5 to 40 Vpp, thereby moving and aligning the ultra-thin LED elements with excellent efficiency into the upper surface of the first electrode while preventing or minimizing damage to the first electrode. If the voltage exceeds 100 Vpp, it may cause the first electrode to be damaged, and during the performance of step 3, there is a concern that the movement and alignment of the ultra-thin LED element may be stopped due to a short circuit of the first electrode, or that the light emission of the ultra-thin LED element may not be smooth during driving due to large damage. In addition, if the voltage is less than 1 Vpp, there is a concern that the proportion of ultra-thin LED elements that are settled into the upper surface of the first electrode will be greatly reduced.

In addition, according to an exemplary embodiment of the present invention, in order to increase the proportion of ultra-thin LED elements 100 that are moved and aligned into the upper surface of each of the first electrodes 211 and 212 by increasing the dominance of electroosmotic pressure on the ultra-thin LED elements 100, in step 1, the viscosity of the solvent 190 in which the ultra-thin LED elements 100 are dispersed may be 50 cP or less, more preferably 5 to 15 cP. If the viscosity of the solvent exceeds 50 cP, there is a concern that the proportion of the number of ultra-thin LED elements moved and aligned into the upper surface is insufficient compared to the number of ultra-thin LED elements injected. In addition, if the viscosity is less than 5 cP, the volatilization speed is fast, so the solvent is insufficient or no longer present in the middle of movement and alignment of the ultra-thin LED elements, thereby making it difficult to secure sufficient process time for movement and alignment. In this case, the viscosity is a viscosity measured with a Brookfield viscometer at 25° C., and a specific measurement method is a known method, and the present invention omits a detailed description thereof.

Next, as step 3, a step of moving the ultra-thin LED elements 100 located in the electric field into the upper surface of each of the first electrodes 211 and 212 is performed.

As described above, the electric field formed by the applied power by appropriately adjusting the frequency may move the ultra-thin LED elements 100 into the upper surface of each of the first electrodes 211 and 212.

Specifically, if steps 1 to 3 are carried out under appropriate conditions according to the present invention, the settling ratio according to Mathematical Equation 1 below corresponding to the proportion of the number of first ultra-thin LED elements 100A, 100B, and 100C, which are ultra-thin LED elements placed on the upper surface of each of the first electrodes 211 and 212 among the total number of ultra-thin LED elements 100 injected in step 1 may be 40% or more, preferably 50% or more, more preferably 60% or more, 65% or more, 75% or more, 80% or more, 85% or more, 89% or more, or 95% or more.

$$First electrode upper surface settling ratio ( \% ) = \frac{\begin{matrix}Number of first ultra - \\ thin LED elements\end{matrix}}{\begin{matrix}Total number of ultra - \\ thin LED elements\end{matrix}} \times 100 \qquad [ Mathematical Equation 1 ]$$

Where, the total number of ultra-thin LED elements refers to the total number of ultra-thin LED elements placed in one subpixel region, and the number of first ultra-thin LED elements refers to the total number of ultra-thin LED elements settled on the upper surface of each of the first electrodes. In addition, the present invention defines that the first ultra-thin LED elements 100A, 100B, and 100C located in the upper surfaces of the first electrodes 211 and 212 are ultra-thin LED elements of which 50% or more of the area is in contact with the upper surfaces of the first electrodes 211 and 212, based on the total area of the contact surface of the ultra-thin LED element in contact with the upper surface of one of the first electrodes 211 and 212. In addition, even if one ultra-thin LED element is in contact with both the upper surfaces of the two first electrodes 211 and 212 due to the narrow spacing between the two adjacent first electrodes 211 and 212, it is considered to belong to the first ultra-thin LED element.

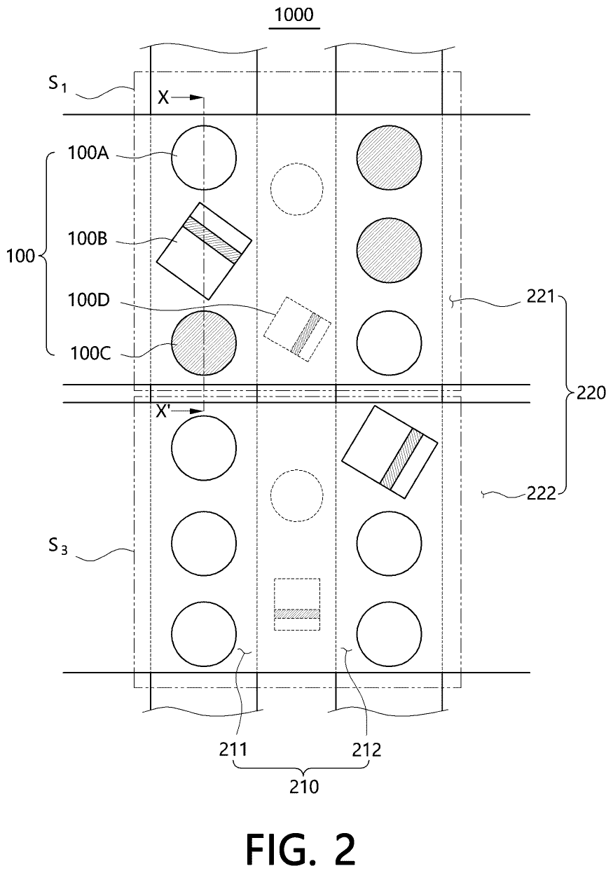

Meanwhile, the ultra-thin LED elements 100 injected in step 1 after going through step 3 may include the first ultra-thin LED elements 100A, 100B, and 100C that are settled and placed on the upper surfaces of the first electrodes 211 and 212, as shown in FIG. 2, and in some cases, may include second ultra-thin LED elements 100D that are not disposed on the upper surfaces of the first electrodes 211 and 212 and are located in a space between the adjacent first electrodes 211 and 212 or are in contact with only one of the first electrodes 211 and 212 but are settled so that the area of the contact surface is less than 50% of the area of one surface of the ultra-thin LED element.

In addition, the first ultra-thin LED elements 100A, 100B, and 100C may be mounted in various forms on the electrode surfaces of the first electrodes 211 and 212. For example, the first ultra-thin LED elements 100A, 100B, and 100C may comprise, among the first surface and the second surface facing each other in the thickness direction in which multiple layers including the first conductive semiconductor layer 110, the photoactive layer 120, and the second conductive semiconductor layer 130 constituting the first ultra-thin LED elements 100A, 100B, and 100C are stacked, a third ultra-thin LED element 100C mounted so that the first surface of the first conductive semiconductor layer 110 is in contact with the upper surface of the first electrode 211, a fourth ultra-thin LED element 100A mounted so that the second surface of the second conductive semiconductor layer 130 is in contact with the upper surface of the first electrode 211, and a fifth ultra-thin LED element 100B mounted so that the reference side surface in the thickness direction is in contact with the upper surface of the first electrode 211. In this case, the fifth ultra-thin LED element 100B among the mounting forms of the first ultra-thin LED elements 100A, 100B, and 100C cannot emit light even when the second electrodes 221 and 222 are formed on the first ultra-thin LED elements 100A, 100B, and 100C through step 4 to be described later. Accordingly, even if the ultra-thin LED elements 100 are moved and aligned into the upper surfaces of the first electrodes 211 and 212 through electroosmotic pressure, there is a concern that the drivable mounting ratio, which is the proportion of ultra-thin LED elements that can emit light when driving power is applied, may not be large enough.

Accordingly, according to an exemplary embodiment of the present invention, the material or structure of the ultra-thin LED elements 100 injected in step 1 described above, and the solvent 190 injected together with them and the frequency and voltage of the power applied in step 2 may be appropriately controlled so that among the total number of first ultra-thin LED elements 100A, 100B, and 100C placed in the upper surfaces of the first electrodes 211 and 212 in one subpixel region S₁,S₂, S₃, S₄, the drivable mounting ratio, which is the total proportion of the number of third ultra-thin LED elements 100C and fourth ultra-thin LED elements 100A that are mounted to be driven is high.

First, the solvent 190 may have a dielectric constant of 5 or more, more preferably 14 or more, more preferably 23 or more, and even more preferably 33 or more in order to increase the proportion of movement and settlement of ultra-thin LED elements 100 into the upper surfaces of the first electrodes 211 and 212 and at the same time increase the drivable mounting ratio. If the dielectric constant of the solvent is less than 5, the ratio of ultra-thin LED elements that move and settle into the upper surface of the first electrode decreases, or even if the ratio of ultra-thin LED elements that move and settle into the upper surface of the first electrode is high, among these ultra-thin LED elements, the ratio of the fifth ultra-thin LED elements (100B) that cannot emit light due to the side surface contacting the upper surface of these ultra-thin LED elements increases significantly, and the luminance of the implemented subpixel region, and further the full-color LED displays may be low. In addition, the solvent 190 may have a dielectric constant of 50 or less, and if the dielectric constant of the solvent exceeds 50, the proportion of ultra-thin LED elements that move and settle into the upper surface of the first electrode or the drivable mounting ratio may rather decrease, and there is a risk of damage to the first electrode.

Next, in the case of the ultra-thin LED element 100 of the present invention, the ultra-thin LED element 100 can be materially/structurally transformed so that the surface properties of the surface constituting the ultra-thin LED element 100 differ between the surfaces in order to increase the ratio of ultra-thin LED elements that move and settle into the upper surfaces of the first electrodes 211 and 212, and at the same time to increase the drivable mounting ratio.

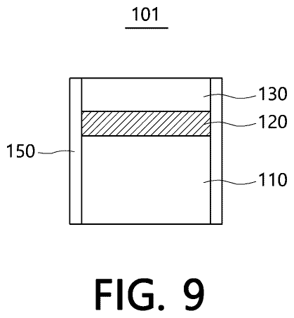

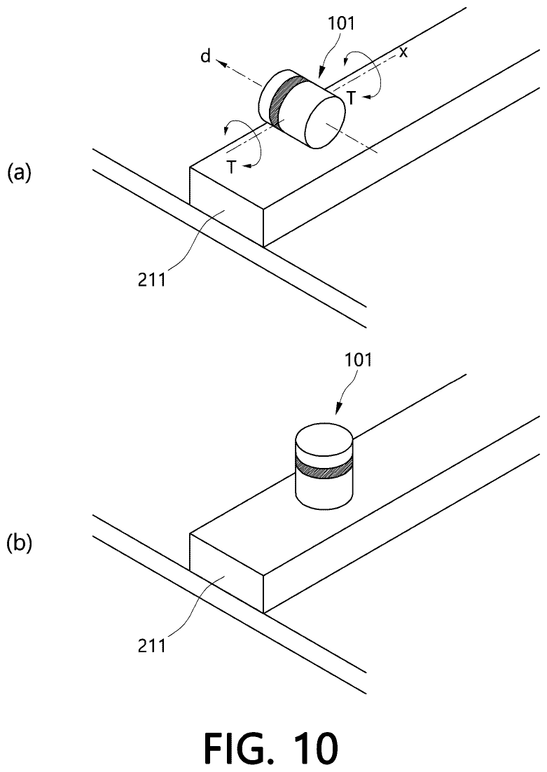

Referring to FIG. 9, for example, the ultra-thin LED element 101 may further include a rotation induction film 150 surrounding the side surface thereof, thereby causing a difference in physical properties through materials between the side surface and the top surface/bottom surface of the ultra-thin LED element 101. As shown in FIG. 10, the difference in physical properties due to the material difference between the side surface and the top surface/bottom surface may cause the ultra-thin LED element 101 to generate a rotational torque (T) based on the x-axis direction perpendicular to the direction (d) in which the layers constituting the ultra-thin LED element 101 are stacked under an electric field. Accordingly, the ultra-thin LED element 101 having a rotation induction film 150 on the side surface may move on the upper surface of the first electrode 211 by electroosmotic pressure and rotate in the x-axis direction to increase the mounting proportion in which the top surface or bottom surface, not the side surface, is in contact with the upper surface. Preferably, the rotation induction film 150 may have a dielectric constant (8) of 30 or less, more preferably 7 or less, and even more preferably 5.5 or less, and may be 3.0 or more as another example, and thus it is advantageous to increase the proportion (or number) of ultra-thin LED elements that are moved and settled on the upper surface of the first electrode while increasing the drivable mounting ratio. If the dielectric constant of the rotation induction film exceeds 30, a sufficient torque may not be exerted, and thus it may be difficult to increase the drivable mounting ratio.

In addition, the rotation induction film 150 may be used without limitation in the case of a material that causes a difference in physical properties from the top surface/bottom surface of the ultra-thin LED element 101, and preferably may be a material that satisfies the above-described dielectric constant conditions. As an example, the rotation induction film may be formed of at least one material among HfO₂, ZrO₂, Al₂O₃, SiO₂, and SiNₓ, and as another example, may be formed of at least one material among Al₂O₃, SiO₂, and SiN_{y}, and as a yet another example, may be formed of at least one material among SiO₂ and SiNₓ.

In addition, according to an exemplary embodiment of the present invention, the aspect ratio of the ultra-thin LED element may be controlled to increase the drivable mounting ratio. Specifically, the ultra-thin LED elements 100, 101, 102 may have a ratio (b/a) of the thickness (b), which is the length in a stacking direction of layers, to the long axis length (a) in the cross-section perpendicular to the stacking direction, greater than 0 and less than or equal to 2.0. If the ratio (b/a) of the thickness (b) to the long axis length (a) exceeds 2.0, the side surface mounting proportion of the ultra-thin LED elements is greatly increased, thereby reducing the drivable mounting ratio or greatly reducing the proportion moving and settling into the electrode surface of the first electrode. More preferably, the ratio (b/a) of the thickness (b) to the long axis length (a) may be greater than 0 to less than or equal to 1.8, thereby greatly improving the drivable mounting ratio and may be advantageous to achieve the object of the present invention. Meanwhile, if the ratio (b/a) of the thickness (b) to the long axis length (a) decreases to greater than 0 to less than 1.0, the ultra-thin LED element settled on the first electrode may increase the probability that the first surface or the second surface will be mounted to contact the first electrode rather than the side surface due to the shape factor of the LED element.

Next, as step 4, a step of forming second electrodes 221 and 222 on the first ultra-thin LED elements 100A, 100B, and 100C placed on the upper surfaces of the first electrodes 211 and 212 is performed.

The number, arrangement, shape, and the like of the second electrodes 221 and 222 are not limited as long as they are designed to be in electrical contact with the upper portions of the first ultra-thin LED elements 100A, 100B, and 100C disposed on the first electrode line 210 described above. However, as shown in FIG. 2, if the first electrode lines 210 are arranged side by side in one direction, each of the second electrodes 221 and 222 may be arranged side by side in a direction perpendicular to the extension direction of the first electrodes 211 and 212, and such an electrode arrangement has the advantage of being able to use the conventional electrode arrangement and driving control technology in the display field as it is, as an electrode arrangement widely used in displays and the like.

Meanwhile, the second electrodes 221 and 222 may have materials, shapes, widths, and thicknesses of electrodes used in conventional displays, and may be manufactured using a known method, and thus the present invention is not specifically limited thereto. For example, the second electrodes 221 and 222 may be aluminum, chromium, gold, silver, copper, graphene, ITO, or an alloy thereof, and may have a width of 2 to 50 μm and a thickness of 0.1 to 100 μm, but may be appropriately changed in consideration of the size, resolution, and the like of a desired display.

In addition, the second electrodes 221 and 222 may be implemented by depositing an electrode material after electrode line patterning using known photolithography or by dry and/or wet etching after depositing the electrode material, and a detailed description of the formation method will be omitted.

Meanwhile, between step 3 and step 4, a step of fixing and insulating each of the aligned first ultra-thin LED elements 100A, 100B, and 100C in contact with the first electrode line 210 and forming a passivation layer 600 on the first electrode line 210 on which the ultra-thin LED elements 100 are placed to provide a surface on which the second electrodes 221 and 222 formed in step 4 are formed may be further included. As the passivation layer 600, when it is a passivation material commonly used in electric and electronic components, it may be used without limitation. For example, the passivation layer 600 may be formed by depositing passivation materials such as SiO₂ and SiNₓ through the PECVD method, depositing passivation materials such as AlN and GaN through the MOCVD method, or depositing passivation materials such as Al₂O, HfO₂, and ZrO₂ through the ALD method. Meanwhile, the passivation layer 600 should be formed so as not to cover the top surface of the magnetically aligned ultra-thin LED element 100, and to this end, a passivation layer may be formed through deposition by a thickness that does not cover the top surface, or after depositing to cover the top surface, dry etching may be performed so that the top surface of the ultra-thin LED element is exposed.

Next, as step 5, a step of patterning a color conversion layer 700 on the upper electrode line 320 may be further performed so that each of the multiple subpixel regions S₁, S₂, S₃, S₄ becomes a subpixel region S₁, S₂, S₃, S₄ expressing any one of blue, green, and red colors.

In the full-color LED display according to the first embodiment, the ultra-thin LED elements 100 provided in the subpixel regions S₁, S₂, S₃, S₄ may emit light colors of blue, white, or UV, and in this case, a color conversion layer 700 capable of converting the emitted light color into another light color light may be provided on the upper portion of the subpixel regions S₁, S₂, S₃, S₄ in order to display the color image. Preferably, in order to improve color reproducibility by further increasing color purity, and to improve the front emission efficiency of color-converted light, for example, green/red, so that the back emission in the color conversion layer is front, a short wavelength transmission filter (not shown) may be formed on top of the subpixel regions S₁, S₂, S₃, S₄, and a color conversion layer 700 may be formed on a region of the top of the short wavelength transmission filter.

In this case, describing based on the case where the ultra-thin LED element 100 is an LED element that emits a blue light color, a short wavelength transmission filter (not shown) may be formed on top of the second electrodes 221 and 222, and as another example, a planarization layer (not shown) for planarizing the plane on which the second electrodes 221 and 222 are formed may be further formed, and then a short wavelength transmission filter may be formed on top of the planarization layer. The short wavelength transmission filter may be a multilayer film made by repeating thin films of high refractive/low refractive materials, and the multilayer film may have [(0.125) SiO₂/(0.25) TiO₂/(0.125) SiO₂]ₘ (m=the number of repeating layers, m is 5 or more) in order to transmit blue color and reflect light colors having a wavelength longer than blue color. In addition, the thickness of the short wavelength transmission filter may be 0.5 to 10 μm, but is not limited thereto. The method for forming the short wavelength transmission filter may be any one of e-beam, sputtering, and atomic vapor deposition, but is not limited thereto.

Next, a color conversion layer 700 may be formed on the short-wavelength transmission filter, and specifically, the color conversion layer 700 may be formed by patterning a green color conversion layer 711 on the short wavelength transmission filter corresponding to some selected subpixel regions among the subpixel regions, and patterning a red color conversion layer 712 on the short wavelength transmission filter corresponding to some selected subpixel regions among the remaining subpixel regions. The method of forming the patterning may be by at least one method selected from the group consisting of screen printing, photolithography, and dispensing. Meanwhile, the patterning order of the green color conversion layer 711 and the red color conversion layer 712 is not limited, and may be formed simultaneously or in reverse order. In addition, the red color conversion layer 712 and the green color conversion layer 711 may be a color conversion layer known in the display field, and for example, may include color conversion materials such as phosphors that can be excited by a color filter or a blue LED element and converted into the desired light color, and known color conversion materials can be used. For example, the green color conversion layer 711 may be a fluorescent layer including a green fluorescent material, and specifically may contain at least one phosphor selected from the group consisting of SrGa₂S₄:Eu, (Sr,Ca)₃SiO₅:Eu, (Sr,Ba,Ca) SiO₄:Eu, Li₂SrSiO₄:Eu, Sr₃SiO₄:Ce, Li, α-SiALON:Eu, CaSc₂O₄:Ce, Ca₃Sc₂Si₃O₁₂:Ce, Caα-SiALON:Yb, Caα-SiALON:Eu, Liα-SiALON:Eu, Ta₃Al₅O₁₂:Ce, Sr₂Si₅N₈:Ce, (Ca, Sr,Ba) Si₂O₂N₂:Eu, Ba₃Si₆O₁₂N₂:Eu, γ-AION:Mn, and γ-AION:Mn,Mg, but is not limited thereto. In addition, the green color conversion layer 711 may be a fluorescent layer containing a green quantum dot material, and specifically may include at least one quantum dot selected from the group consisting of CdSe/ZnS, InP/ZnS, InP/GaP/ZnS, InP/ZnSe/ZnS, and Perovskite green nanocrystals, but is not limited thereto.

In addition, the red color conversion layer 712 may be a fluorescent layer containing a red fluorescent material, and specifically may include at least one phosphor selected from the group consisting of (Sr, Ca) AlSiN₃:Eu, CaAlSiN₃:Eu, (Sr,Ca) S:Eu, CaSiN₂:Ce, SrSiN₂:Eu, Ba₂Si₅N₈:Eu, CaS:Eu, CaS:Eu,Ce, SrS:Eu, SrS:Eu,Ce, and Sr₂Si₅N₈:Eu, but is not limited thereto. In addition, the red color conversion layer may be a fluorescent layer containing a red quantum dot material, and specifically may include at least one quantum dot selected from the group consisting of CdSe/ZnS, InP/ZnS, InP/GaP/ZnS, InP/ZnSe/ZnS, and Perovskite red nanocrystals, but is not limited thereto.

In some subpixel regions, only a short wavelength transmission filter is disposed on the uppermost layer and a green color conversion layer and a red color conversion layer are not formed on the vertical top, and blue light may be irradiated from these regions. On the other hand, green light may be irradiated through the green color conversion layer 711 in some subpixel regions in which the green color conversion layer 711 is formed on the top of the short wavelength transmission filter. In addition, red light may be irradiated in the remaining subpixel regions as the red color conversion layer 712 is formed on top of the short wavelength transmission filter, thereby implementing a color-by-blue LED display as the first embodiment.

In addition, preferably, a long wavelength transmission filter may be formed on the top, including the green color conversion layer 711 and the red color conversion layer 712, and the long wavelength transmission filter functions as a filter for preventing color purity from falling due to the mixture of blue light emitted from the ultra-thin LED element 100 and color-converted green/red light. The long wavelength transmission filter may be formed on top of a part or all of the green color conversion layer and the red color conversion layer, and preferably, may be formed only on the green/red color conversion layer. In this case, the long wavelength transmission filter that can be used may be a multilayer film made by repeating thin films of high refractive/low refractive materials that can achieve the purpose of long-wavelength transmission and short-wavelength reflection that reflects blue color, and the composition may be [(0.125) TiO₂/(0.25) SiO₂/(0.125) TiO₂]ₘ (m=the number of repeating layers, m is 5 or more). In addition, the thickness of the long wavelength transmission filter 1950 may be 0.5 to 10 μm, but is not limited thereto. The method for forming the long wavelength transmission filter may be any one of e-beam, sputtering, and atomic vapor deposition, but is not limited thereto. In addition, in order to form a long wavelength transmission filter only on top of the green/red color conversion layer, a long wavelength transmission filter may be formed only on a desired region by using a metal mask that may expose the green/red color conversion layer and mask other than that.

Meanwhile, the color conversion layer 700 was based on an ultra-thin LED element that emits blue light color, but if an ultra-thin LED element that emits UV light is provided, a blue color conversion layer 713 for changing to a blue light color may be provided on a subpixel region in which the above-described green color conversion layer 711 and red color conversion layer 712 are not provided, and in this case, a known phosphor or quantum dot may be used as the blue color conversion layer 713, and thus a detailed description thereof is omitted in the present invention.

The full-color LED display 1000 according to the first embodiment implemented through the above-described manufacturing method includes multiple subpixel regions S₁, S₂, S₃, S₄, wherein each of the subpixel regions S₁,S₂, S₃, S₄ includes a first electrode line 210 including at least two first electrodes 211 and 212 spaced apart from each other in their side surfaces, multiple ultra-thin LED elements 100 including first ultra-thin LED elements 100A, 100B, and 100C disposed on the upper surfaces of the first electrodes 211 and 212, and second electrodes 221 and 222 disposed on the first ultra-thin LED elements 100A, 100B, and 100C, and is implemented such that the settling ratio in the upper surfaces of the first electrodes 211 and 212 calculated according to Mathematical Equation 1 below is 40% or more, preferably 50% or more, more preferably 60% or more, 65% or more, 75% or more, 80% or more, 85% or more, 89% or more, or 95% or more.

$$First electrode upper surface settling ratio ( \% ) = \frac{\begin{matrix}Number of first ultra - \\ thin LED elements\end{matrix}}{\begin{matrix}Total number of ultra - \\ thin LED elements\end{matrix}} \times 100 \qquad [ Mathematical Equation 1 ]$$

Where, the total number of ultra-thin LED elements refers to the total number of ultra-thin LED elements 100 placed in one subpixel region, and the number of first ultra-thin LED elements refers to the total number of ultra-thin LED elements 100A, 100B, 100C settled on the upper surface of each of the first electrodes.

In addition, the first ultra-thin LED elements 100A, 100B, 100C may preferably be mounted to have a drivable mounting ratio, which is a proportion of the total number of the third ultra-thin LED elements 100B and the fourth ultra-thin LED elements 100A mounted so that the top surface and the bottom surface of the first ultra-thin LED elements 100A, 100B, 100C are in contact with the first electrodes 211 and 212 and the second electrodes 221 and 222, of 40% or more, as another example, 45% or more, 50% or more, 60% or more, or 70% or more, and accordingly, the driving rate and luminance of the ultra-thin LED elements 100 provided in the full-color LED display 1000 may be increased.

In addition, at least two first ultra-thin LED elements 100A, 100B, 100C may be arranged for each of the multiple subpixel regions S₁, S₂, S₃, S₄, and accordingly, even when a defective element is included or a contact failure occurs in some of the first ultra-thin LED elements 100A, 100B, 100C disposed in each subpixel region, the remaining first ultra-thin LED elements 100A, 100B, 100C may emit light, so all subpixel regions S₁, S₂, S₃, S₄ may ultimately emit light, thereby preventing the occurrence of defective pixels in the display.

In addition, the ultra-thin LED elements 100 provided in each of the subpixel regions S₁, S₂, S₃, S₄ emits substantially the same light color. In this case, the substantially same light color does not mean that the wavelength of the emitted light is completely the same, but it generally means light belonging to a wavelength region that can be called the same light color. For example, when the light color is blue, it can be considered that all ultra-thin LED elements that emit light within the wavelength region of 420 to 470 nm emit substantially the same light color. The light color emitted by the ultra-thin LED element provided in the display according to the first embodiment of the present invention may be, for example, blue, white, or UV.

In addition, as shown in FIG. 2, a color conversion layer 700 in which a blue color conversion layer 713, a green color conversion layer 711, and a red color conversion layer 712 are patterned is included on the second electrodes 221 and 222 so that each of the multiple subpixel regions may be a subpixel region that independently expresses any one of blue, green, and red colors. Since the blue color conversion layer 713, the green color conversion layer 711, and the red color conversion layer 712 may be a known color conversion layer that converts light passing through the color conversion layer to have blue, green, and red in consideration of the wavelength of light emitted by the ultra-thin LED element 100 provided in the subpixel region, the present invention is not particularly limited in this regard. Meanwhile, when the ultra-thin device 100 is a device that emits blue light, the blue color conversion layer 713 is unnecessary, so the color conversion layer 700 may include a green color conversion layer 711 and a red color conversion layer 712.

In addition, a protective layer 800 may be further provided to protect the color conversion layer 700 described above, and the protective layer 800 may appropriately employ a protective layer used in a conventional display in which the color conversion layer 700 is provided, so the present invention is not particularly limited in this regard.

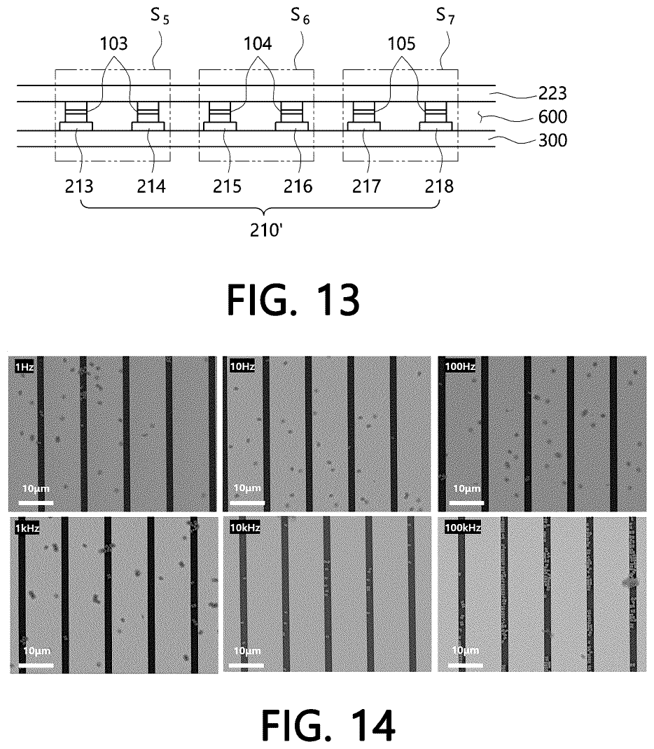

Next, describing a full-color display 2000 according to a second embodiment of the present invention with reference to FIGS. 12 and 13, the full-color LED display 2000 may be manufactured by including a step of injecting a solution containing ultra-thin LED elements 103,104,105 with a light color designated for each subpixel region S₅, S₆, S₇ so that multiple subpixel regions S₅, S₆, S₇ including a blue subpixel region S₅, a green subpixel region S₆, and a red subpixel region S₇ are formed in each of which a first electrode line 210′ including at least two first electrodes 213/214, 215/216, 217/218 spaced apart from each other so that each side surface faces each other is disposed (step A), a step of forming an electric field by applying a power having a frequency of 500 Hz or less to the first electrodes 213/214, 215/216, 217/218 (step B), a step of moving the ultra-thin LED elements 103, 104, 105 located in the electric field into the upper surface of each of the first electrodes 213/214, 215/216, 217/218 (step C), and a step of forming a second electrode 223 on the ultra-thin LED elements 103, 104, 105 disposed within the upper surfaces of the first electrodes 213/214, 215/216, 217/218 (step D).

The method for manufacturing the full-color LED display 2000 according to the second embodiment is the same as the method for manufacturing the full-color LED display 1000 according to the first embodiment described above, except that each of the injected ultra-thin LED elements 103, 104, 105 is made up of ones having three different light colors, such as blue, green, and red, that the ultra-thin LED elements in the ultra-thin LED element solution injected into one subpixel region are made up of ones having one light color of the three light colors, for example, and thus that a separate color conversion layer for realizing the color may be omitted, and accordingly, hereinafter, a detailed description of the specific manufacturing method of the display according to the second embodiment will be omitted.

In addition, the full-color LED display 2000 according to the second embodiment implemented through the such manufacturing method includes multiple subpixel regions S₅, S₆, S₇ including a blue subpixel region S₅, a green subpixel region S₆, and a red subpixel region S₇, wherein each of the subpixel regions S₅, S₆, S₇ includes a first electrode line 210′ including at least two first electrodes 213/214, 215/216, 217/218 spaced apart from each other in their side surfaces, first ultra-thin LED elements disposed on the upper surfaces of the first electrodes 213/214, 215/216, 217/218, and multiple ultra-thin LED elements 103, 104, 105 having a designated light color, and a second electrode 223 disposed on the first ultra-thin LED element, and is implemented such that the settling ratio in the upper surfaces of the first electrodes 213/214, 215/216, 217/218 calculated according to Mathematical Equation 1 below is 40% or more, preferably 50% or more, more preferably 60% or more, 65% or more, 75% or more, 80% or more, 85% or more, 89% or more, or 95% or more.

$$First electrode upper surface settling ratio ( \% ) = \frac{\begin{matrix}Number of first ultra - \\ thin LED elements\end{matrix}}{\begin{matrix}Total number of ultra - \\ thin LED elements\end{matrix}} \times 100 \qquad [ Mathematical Equation 1 ]$$

Where, the total number of ultra-thin LED elements refers to the total number of ultra-thin LED elements placed in one subpixel region, and the number of first ultra-thin LED elements refers to the total number of ultra-thin LED elements settled on the upper surface of each of the first electrodes.

In addition, the first ultra-thin LED elements placed in one subpixel region may preferably be mounted to have a drivable mounting ratio, which is a proportion of the total number of the ultra-thin LED elements mounted so that the top surface and the bottom surface of the first ultra-thin LED elements are in contact with the first electrodes 213/214, 215/216, 217/218 and the second electrodes 223, of 40% or more, as another example, 45% or more, 50% or more, 60% or more, or 70% or more, and accordingly, the driving rate and luminance of the ultra-thin LED elements 103,104,105 provided in the full-color LED display 2000 may be increased.

In addition, at least two first ultra-thin LED elements may be arranged for each of the multiple subpixel regions S₅, S₆, S₇, and accordingly, even when a defective element is included or a contact failure occurs in some of the first ultra-thin LED elements disposed in each subpixel region, the remaining first ultra-thin LED elements may emit light, so all subpixel regions S₅, S₆, S₇ may ultimately emit light, thereby preventing the occurrence of defective pixels in the display.

The present invention will be described in more detail through the following examples, but the following examples are not intended to limit the scope of the present invention, which should be construed to aid understanding of the present invention.

### Example 1

First, ultra-thin LED elements were prepared as follows. Specifically, a conventional LED wafer (Epistar) was prepared by sequentially stacking an undoped n-type III-nitride semiconductor layer, an n-type III-nitride semiconductor layer doped with Si (4 μm thick), a photoactive layer (0.15 μm thick), and a p-type III-nitride semiconductor layer (0.05 μm thick) on a substrate. SiO₂ (0.9 μm thick) as a first mask layer and Al (200 nm thick) as a second mask layer were sequentially deposited on the prepared LED wafer, and then a SOG resin layer on which a circular pattern with a diameter of 0.55 nm was transferred, was transferred onto the second mask layer using nanoimprint equipment. Thereafter, the SOG resin layer was cured using RIE, and the residual resin portion of the resin layer was etched through RIE to form a resin pattern layer. Thereafter, the second mask layer was etched using ICP along the pattern, and the first mask layer was etched using RIE. Thereafter, after etching the first electrode layer, p-type III-nitride semiconductor layer, and photoactive layer using ICP, the doped n-type III-nitride semiconductor layer was then etched to a thickness of 0.8 μm, and an LED wafer with multiple LED structures formed with the mask pattern layer removed was manufactured through KOH wet etching. Then, a temporary protective film, which is SiO₂, was deposited on the LED wafer where the multiple LED structures were formed (72 nm deposition thickness based on the side of the LED structure), and then the temporary protective film material formed between the multiple LED structures was removed through RIE to expose the top surface of the doped n-type III-nitride semiconductor layer between the LED structures.

Afterwards, the LED wafer on which the temporary protective film was formed was impregnated with an electrolyte of 0.3 M oxalic acid aqueous solution and connected to an anode terminal of the power source, and a cathode terminal was connected to a platinum electrode impregnated with the electrolyte, and then a voltage of 15V was applied for 5 minutes to form multiple pores in the thickness direction from the surface of the doped n-type III-nitride semiconductor layer between the LED structures. Afterwards, the temporary protective film was removed through ICP, the LED wafer was immersed in a 100% gamma-butyrolactone bubble-forming solution, and the pores formed in the doped n-type III-nitride semiconductor layer were collapsed using the bubbles generated by irradiating ultrasonic waves at 160 W and 40 kHz for 10 minutes to manufacture multiple ultra-thin LED elements (720 nm in diameter, 800 nm in thickness).

Afterwards, in order to implement one subpixel region, a first electrode line was manufactured in which multiple first electrodes extending in a first direction were alternately formed to have a spacing of 2 μm in a second direction perpendicular to the first direction on a base substrate made of quartz with a thickness of 500 μm. In this case, the width of the first electrode is 10 μm and the thickness is 0.2 μm, the material of the first electrode is gold, and the area of the region where the ultra-thin LED elements are mounted in the first electrode line is set to 1 mm². In addition, an insulating partition wall, which is made of SiO₂, with a height of 0.5 μm was formed on the base substrate to surround the mounted region above.

After preparing a solution in which 200 prepared ultra-thin LED elements were mixed with acetone with a dielectric constant of 20.7, the prepared solution was dropped twice by 9 μl in the mounted region, and AC power of sine waves of 1 Hz and 10Vpp was applied as power to the adjacent first electrodes to magnetically align the ultra-thin LED elements.

After that, a subpixel region was implemented by depositing SiO₂ passivation material at a height corresponding to the thickness of the ultra-thin LED element on the region where the ultra-thin LED elements were mounted using the PECVD method, and then forming multiple second electrodes (10 μm wide, 0.2 μm thick, 2 μm spacing between electrodes, and gold material) extending in the second direction perpendicular to the first direction and spaced apart from each other in the first direction on the top surface of the mounted ultra-thin LED elements, and a full-color LED display with multiple subpixel regions was implemented in this way.

### Examples 2 to 12

Although manufactured in the same manner as in Example 1, a full-color LED display was implemented by changing the frequency and/or voltage of the power applied to the first electrode as shown in Table 1 below.

### Comparative Examples 1 to 4

Although manufactured in the same manner as in Example 1, a full-color LED display was implemented by changing the frequency of the power applied to the first electrode as shown in Table 1 below.

### Experimental Example 1

In the full-color LED display according to Examples 1 to 12 and Comparative Examples 1 to 4, the proportion of the ultra-thin LED elements settled onto the upper surfaces of the first electrodes to the total number of ultra-thin LED elements injected for one subpixel region was evaluated as follows, and the results are shown in Table 1 below.

Specifically, after power was applied during the full-color LED display manufacturing process, a SEM photo was taken while the ultra-thin LED elements were magnetically aligned, and the number of first ultra-thin LED elements settled in the upper surface of the first electrode within the unit area (1 mm²) of the first electrode line was counted and shown in Table 1 below as a percentage of the number of ultra-thin LED elements injected in. In addition, SEM photographs of some regions measured in connection with Examples 1 to 4 and Comparative Examples 2 to 3 are shown in FIG. 14.

In addition, for Examples 1, 9, and 10, whether the first electrode line was damaged was observed through an optical microscope.

As a result of observation, in Examples 1 and 9, damage to the first electrode line was not observed, but in Example 10, it was confirmed that a color of a part of the first electrode line was changed and damage to the electrode may occur, and it may be expected that a problem such as a short circuit of the electrode may occur if the applied voltage is higher.

TABLE 1

| | Applied power | | Settling Ratio Within |
|---|---|---|---|
| | Frequency | Voltage | Upper Surface of |
| | (Hz) | (Vpp) | First Electrode (%) |
| Example 1 | 1 | 10 | 66.0 |
| Example 2 | 5 | 10 | 85.1 |
| Example 3 | 10 | 10 | 89 |
| Example 4 | 100 | 10 | 41.2 |
| Example 5 | 500 | 50 | 40.3 |
| Example 6 | 10 | 1 | 65.2 |
| Example 7 | 10 | 5 | 76.8 |
| Example 8 | 10 | 20 | 93.0 |
| Example 9 | 10 | 40 | 95.1 |
| Example 10 | 10 | 100 | 98.2 |
| Example 11 | 30 | 5 | 67.6 |
| Example 12 | 50 | 5 | 52.3 |
| Comparative Example 1 | 1000 | 10 | 22.3 |
| Comparative Example 2 | 2000 | 50 | 18.5 |
| Comparative Example 3 | 1 × 10⁴ | 50 | 15.3 |
| Comparative Example 4 | 1 × 10⁵ | 50 | 12.1 |

As can be seen through Table 1 and FIG. 14, it can be seen that in Examples 1 to 12 in which the frequency of the applied power is 500 Hz or less, the settling ratio of the ultra-thin LED elements in the upper surface of the first electrode is at least two times higher than that of Comparative Examples 1 to 4.

### Examples 13 to 18

Although manufactured in the same manner as in Example 3, a full-color LED display was manufactured by changing the type of solvent for dispersing the ultra-thin LED elements as shown in Table 2 below instead of acetone.

### Experimental Example 2

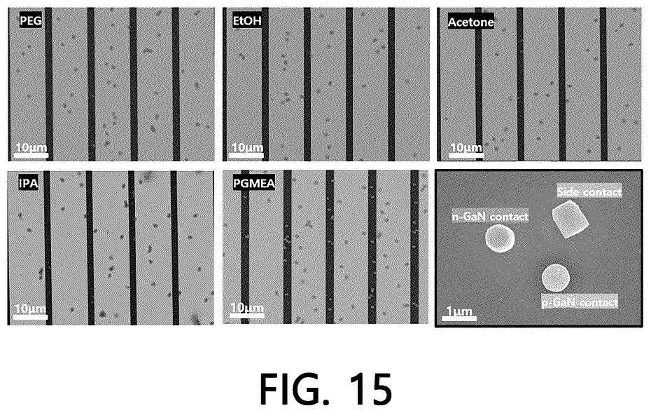

One subpixel region in the full-color LED display according to Examples 3 and 13 to 18 was evaluated in the same manner as in Experimental Example 1, and SEM photographs were used to observe and count the ultra-thin LED settlement proportion in the upper surface of the first electrode, and whether the surface of the ultra-thin LED element in contact with the upper surface of the first electrode was an upper layer on the side of the p-type conductive semiconductor layer, a lower layer on the side of the n-type conductive semiconductor layer, or a side surface. Specifically, among all ultra-thin LED elements settled in the upper surface, the number of LED elements in the first group where the lower layer on the side of the n-type conductive semiconductor layer contacts the upper surface, and the number of LED elements in the second group where the upper layer on the side of the p-type conductive semiconductor layer contacts the upper surface, were counted, and the drivable mounting ratio among all ultra-thin LED elements settled in the upper surface was calculated and shown in Table 2 below. In addition, some SEM photos of the mounting region within one subpixel region in the full-color LED display according to Examples 3 and 13 to 16 are shown in FIG. 15.

TABLE 2

| | | Settling Ratio | |
|---|---|---|---|
| | | Within Upper | Drivable |
| | Solvent | Surface of First | mounting |
| | (type/dielectric constant) | Electrode (%) | ratio (%) |
| Example 13 | PEG/35.5 | 99.69 | 60.51 |
| Example 14 | Ethanol/24.3 | 99.54 | 43.94 |
| Example 3 | Acetone/20.7 | 89 | 19.4 |
| Example 15 | Isopropyl alcohol/18.0 | 87.7 | 15.7 |
| Example 16 | Propylene glycol methyl | 63.87 | 12.44 |
| | ether acetate (PGMEA)/8.3 | | |
| Example 17 | Hexane/2.02 | 5.21 | 0.8 |
| Example 18 | Water (H₂O)/79.9 | 24.21 | 2 |

As can be seen from Table 2, the number of ultra-thin LED elements mounted on the first electrode is greatly reduced in Example 17 in which the dielectric constant of the solvent is less than 5 and Example 18 in which the dielectric constant is greater than 50.

### Examples 19 to 31

It was manufactured in the same manner as in Example 3, but a full-color LED display was manufactured using ultra-thin LED elements in which a rotation induction film was formed on the side surface of the ultra-thin LED elements or the thickness was adjusted, by changing the manufacturing process of ultra-thin LED elements as shown in Table 3 below.

In this case, the rotation induction film was formed on the side surface of an ultra-thin LED element by forming multiple pores on the LED wafer with a large number of LED structures formed therein, removing the temporary protective film through ICP, depositing the rotation induction film material at a thickness of 60 nm based on the side surface of the LED structure before immersing the LED wafer in a 100% gamma-butyrolactone bubble formation solution, and then removing the rotation induction film material formed between the LED structures through RIE to expose the top surface of the doped n-type III-nitride semiconductor layer between the LED structures.

In addition, the thickness change of the ultra-thin LED element was controlled by changing the depth of etching the LED wafer.

### Experimental Example 3

One subpixel region in the full-color LED display according to Examples 3 and 19 to 31 was evaluated in the same manner as in Experimental Example 1, and the ultra-thin LED settlement proportion and the drivable mounting ratio in the upper surface of the first electrode were calculated and shown in Table 3 below.

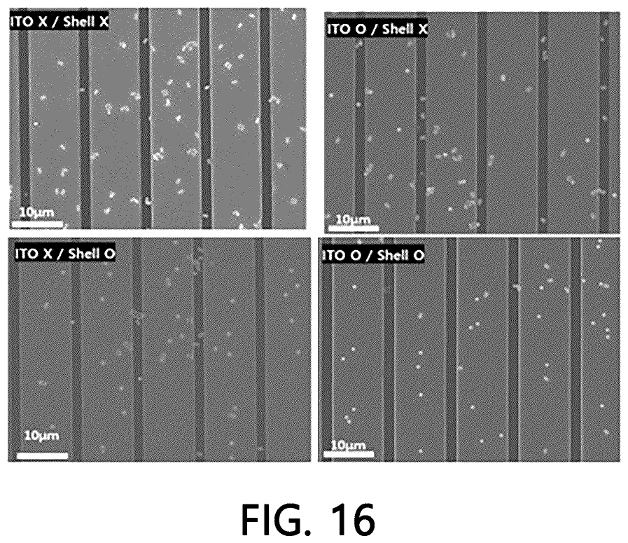

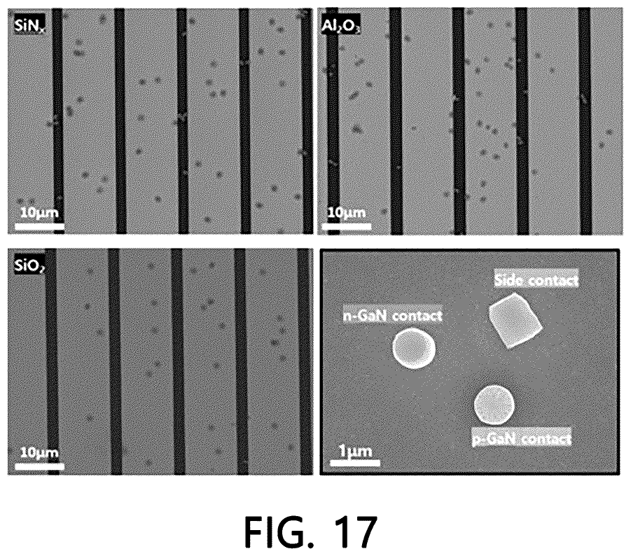

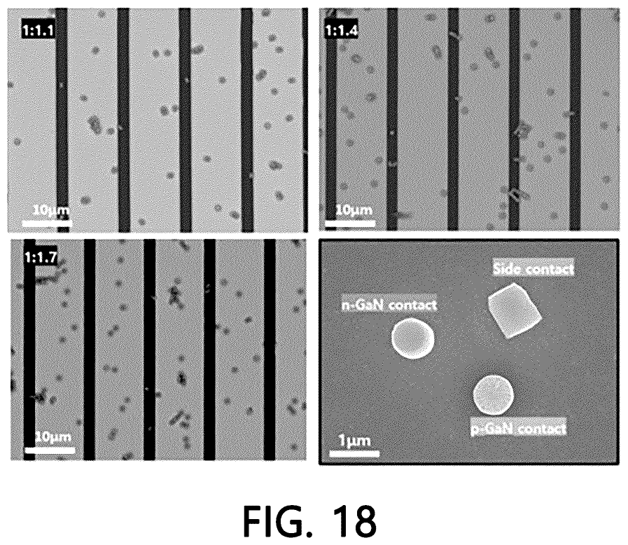

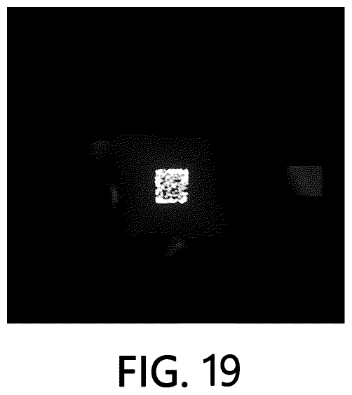

In addition, in the full-color LED display according to Examples 3 and 19 to 21, some SEM photographs of the mounting region within one subpixel region are shown in FIG. 16, and in the full-color LED display according to Examples 22 to 24, some SEM photographs of the mounting region within one subpixel region are shown in FIG. 17, and in the full-color LED display according to Examples 21 and 25 to 26, some SEM photographs of the mounting region within one subpixel region are shown in FIG. 18.

TABLE 3

| | | | | Settling | | | | | |
|---|---|---|---|---|---|---|---|---|---|
| | Ultra-thin LED element | | | Ratio | | | | | |
| | | Rotation | | Within | | | | | |
| | Top | induction | | Upper | Proportion per contact surface of ultra- | | | | |
| | layer on | film | | Surface of | thin LED elements settled in upper | | | | |
| | p-type | (material/ | Thickness | First | surface of first electrode (%) | | | | Drivable |
| | semiconductor | dielectric | (b)/diameter | Electrode | n-type | side | p-type | | mounting |
| | side | constant) | (a) ratio | (%) | semiconductor | surface | semiconductor | Total | ratio (%) |
| Example | none | none | 1.11 | 93.87 | 12.9 | 76.9 | 10.2 | 100 | 23.1 |
| 3 | | | | | | | | | |
| Example | ITO | none | 1.11 | 80.32 | 6.8 | 76.4 | 16.8 | 100 | 23.6 |
| 19 | | | | | | | | | |
| Example | none | SiO₂/3.9 | 1.11 | 85.2 | 4.0 | 28.2 | 67.8 | 100 | 71.8 |
| 20 | | | | | | | | | |
| Example | ITO | SiO₂/3.9 | 1.11 | 99.69 | 4.3 | 28.8 | 66.9 | 100 | 71.2 |
| 21 | | | | | | | | | |
| Example | ITO | SiO₂/3.9 | 1.4 | 89.71 | 5.7 | 27.8 | 66.5 | 100 | 72.2 |
| 22 | | | | | | | | | |
| Example | ITO | SiNx/6.2 | 1.4 | 89.15 | 8.0 | 49.3 | 42.7 | 100 | 50.7 |
| 23 | | | | | | | | | |
| Example | ITO | Al₂O₃/9.0 | 1.4 | 87.5 | 14.2 | 64.0 | 21.8 | 100 | 36.0 |
| 24 | | | | | | | | | |
| Example | ITO | SiO₂/3.9 | 1.74 | 92.1 | 14.2 | 28.0 | 57.8 | 100 | 72.0 |
| 25 | | | | | | | | | |
| Example | ITO | SiO₂/3.9 | 1.95 | 80.12 | 36.9 | 44.6 | 18.5 | 100 | 55.4 |
| 26 | | | | | | | | | |
| Example | ITO | SiO₂/3.9 | 2.5 | 75.12 | 2.9 | 92.3 | 4.8 | 100 | 7.7 |
| 27 | | | | | | | | | |
| Example | none | ZrO₂/25.0 | 1.1 | 83.1 | 28.2 | 57.5 | 14.3 | 100 | 42.5 |
| 28 | | | | | | | | | |
| Example | none | HfO₂/30 | 1.1 | 81.1 | 25.8 | 59.8 | 14.4 | 100 | 40.2 |
| 29 | | | | | | | | | |
| Example | none | TiO₂/80 | 1.1 | 76.5 | 4.1 | 87.9 | 8.0 | 100 | 12.1 |
| 30 | | | | | | | | | |

As can be seen from Table 3, it can be seen that in the Examples, the settlement proportion of the ultra-thin LED elements in the upper surface of the first electrode is 76.5% or more, and the efficiency of moving and settling the ultra-thin LED elements dispersed in the solvent to the upper surface of the first electrode is very excellent.

In addition, it can be seen that the Examples provided with the rotation induction film have a high proportion of being mounted to be driven compared to Examples 3 and 19 without the rotation induction film. However, in the case of Example 27, where the thickness (b)/diameter (a) ratio of the ultra-thin LED element exceeds 2.0, and Example 30, where the dielectric constant of the rotation induction film is excessive, the drivable mounting ratio is significantly reduced compared to other Examples.

Although exemplary embodiments of the present invention have been described above, the idea of the present invention is not limited to the embodiments set forth herein. Those of ordinary skill in the art who understand the idea of the present invention may easily propose other embodiments through supplement, change, removal, addition, etc. of elements within the scope of the same idea, but the embodiments will be also within the idea scope of the present invention.

1. A method for manufacturing a full-color LED display, the method comprising:
injecting a solution containing ultra-thin LED elements into multiple subpixel regions in each of which a first electrode line comprising at least two first electrodes spaced apart from each other so that side surfaces of the first electrodes face each other are arranged;
forming an electric field by applying power having a frequency of 500 Hz or less to the first electrode line;
moving the ultra-thin LED elements located in the electric field into an upper surface of the first electrode; and
forming a second electrode on the ultra-thin LED element disposed within the upper surface of the first electrode.

2. The method of claim 1,
wherein the ultra-thin LED elements have substantially the same light color, and
wherein the method further comprises, after forming the second electrode, patterning a color conversion layer on the second electrode corresponding to each subpixel region so that the multiple subpixel regions are independently blue, green, or red subpixel regions.

3. The method of claim 1,
wherein the solution containing ultra-thin LED elements includes three types of solutions each containing blue ultra-thin LED elements, green ultra-thin LED elements, and red ultra-thin LED elements, and
wherein a solution containing ultra-thin LED elements with a light color designated for each subpixel region is injected so that multiple subpixel regions comprise blue, green, and red subpixel regions.

4. The method of claim 1, wherein the power has a frequency of 1 to 500 Hz and a voltage of 5 to 100 Vpp.

5. The method of claim 1, wherein the viscosity of a solvent in the solution is 50 cP or less.

6. The method of claim 1, wherein the dielectric constant (E) of a solvent in the solution is 5 to 50.

7. The method of claim 1, wherein the ultra-thin LED element is made by stacking layers including a first conductive semiconductor layer, a photoactive layer, and a second conductive semiconductor layer, and a rotation induction film is further provided for surrounding a side surface of the ultra-thin LED element to generate a rotation torque based on an axial direction perpendicular to a direction in which the layers are stacked.

8. The method of claim 7, wherein the dielectric constant (E) of the rotation induction film is 3 to 26.

9. The method of claim 8, wherein the ultra-thin LED element has a ratio (b/a) of a thickness (b), which is a length in a stacking direction of layers, to a long axis length (a) in the cross-section perpendicular to the stacking direction, greater than 0 and less than or equal to 2.0.

10. The method of claim 9, wherein the ratio (b/a) of the ultra-thin LED element is greater than 0 and less than or equal to 1.8.

11. A full-color LED display, comprising:
multiple subpixel regions,
wherein each subpixel region comprises:
a first electrode line comprising at least two first electrodes whose side surfaces are spaced apart from each other;
multiple ultra-thin LED elements each comprising a first ultra-thin LED element disposed in an upper surface of the first electrode; and
a second electrode disposed on the first ultra-thin LED element, and
wherein the settling ratio in the upper surface of the first electrode calculated according to Mathematical Equation 1 below satisfies 40% or more:
$$First electrode upper surface settling ratio ( \% ) = \frac{\begin{matrix}Number of first ultra - \\ thin LED elements\end{matrix}}{\begin{matrix}Total number of ultra - \\ thin LED elements\end{matrix}} \times 100 \qquad [ Mathematical Equation 1 ]$$
where, the total number of ultra-thin LED elements refers to the total number of ultra-thin LED elements placed in one subpixel region, and the number of first ultra-thin LED elements refers to the total number of ultra-thin LED elements settled on the upper surface of each of the first electrodes.

12. A full-color LED display, comprising:
multiple subpixel regions including blue, green and red subpixel regions,
wherein each subpixel region comprises:
a first electrode line comprising at least two first electrodes whose side surfaces are spaced apart from each other;
multiple ultra-thin LED elements each comprising a first ultra-thin LED element disposed in an upper surface of the first electrode and having a designated light color; and
a second electrode disposed on the first ultra-thin LED element, and
wherein the settling ratio in the upper surface of the first electrode calculated according to Mathematical Equation 1 below satisfies 40% or more:
$$First electrode upper surface settling ratio ( \% ) = \frac{\begin{matrix}Number of first ultra - \\ thin LED elements\end{matrix}}{\begin{matrix}Total number of ultra - \\ thin LED elements\end{matrix}} \times 100 \qquad [ Mathematical Equation 1 ]$$
where, the total number of ultra-thin LED elements refers to the total number of ultra-thin LED elements placed in one subpixel region, and the number of first ultra-thin LED elements refers to the total number of ultra-thin LED elements settled on the upper surface of each of the first electrodes.

13. The full-color LED display of claim 11, further comprising, for each subpixel region, a color conversion layer patterned on the second electrode corresponding to the subpixel region so that each subpixel region become a subpixel region expressing any one of blue, green, and red colors.

14. The full-color LED display of claim 11,
wherein the ultra-thin LED element is made by stacking layers including a first conductive semiconductor layer, a photoactive layer, and a second conductive semiconductor layer, and comprises a first surface and a second surface facing each other in the thickness direction, and
wherein among the number of first ultra-thin LED elements in one subpixel region, a drivable mounting ratio, which is a ratio of the total sum of the number of third ultra-thin LED elements mounted so that the first surface is in contact with the upper surface of the first electrode and the second surface is in contact with a second electrode line and the number of fourth ultra-thin LED elements mounted so that the second surface is in contact with the upper surface of the first electrode and the first surface is in contact with the second electrode line, is 40% or more.

15. The full-color LED display of claim 11, wherein the spacing between the adjacent first electrodes is 2 to 10 μm.

16. The full-color LED display of claim 11, wherein the ultra-thin LED element has a thickness of 0.5 to 1.5 μm, which is the length in a direction in which the layers are stacked, and a long axis length in the cross-section perpendicular to the stacking direction of the layers of 0.5 to 3.0 μm.

17. The full-color LED display of claim 15, wherein the settling ratio in the upper surface of the first electrode calculated according to Mathematical Equation 1 is 80% or more, and the drivable mounting ratio is 50% or more.

18. The full-color LED display of claim 12,
wherein the ultra-thin LED element is made by stacking layers including a first conductive semiconductor layer, a photoactive layer, and a second conductive semiconductor layer, and comprises a first surface and a second surface facing each other in the thickness direction, and
wherein among the number of first ultra-thin LED elements in one subpixel region, a drivable mounting ratio, which is a ratio of the total sum of the number of third ultra-thin LED elements mounted so that the first surface is in contact with the upper surface of the first electrode and the second surface is in contact with a second electrode line and the number of fourth ultra-thin LED elements mounted so that the second surface is in contact with the upper surface of the first electrode and the first surface is in contact with the second electrode line, is 40% or more.

19. The full-color LED display of claim 12, wherein the spacing between the adjacent first electrodes is 2 to 10 μm.

20. The full-color LED display of claim 12, wherein the ultra-thin LED element has a thickness of 0.5 to 1.5 μm, which is the length in a direction in which the layers are stacked, and a long axis length in the cross-section perpendicular to the stacking direction of the layers of 0.5 to 3.0 μm.

21. The full-color LED display of claim 19, wherein the settling ratio in the upper surface of the first electrode calculated according to Mathematical Equation 1 is 80% or more, and the drivable mounting ratio is 50% or more.
